(19) United States
(12) Patent Application Publication
(10) Pub. No.: US 2024/0260288 A1
(43) Pub. Date: Aug. 1, 2024

(54) HIGH MOLECULAR WEIGHT TRIARYLAMINE COMPOUNDS, AND ORGANIC ELECTROLUMINESCENT ELEMENTS CONTAINING THESE HIGH MOLECULAR WEIGHT COMPOUNDS

(71) Applicant: HODOGAYA CHEMICAL CO., LTD., Tokyo (JP)

(72) Inventors: Kazunori TOGASHI, Tokyo (JP); Yuta SAEGUSA, Tokyo (JP); Mika SHINODA, Tokyo (JP); Hideyoshi KITAHARA, Tokyo (JP); Hiroki HIRAI, Tokyo (JP)

(73) Assignee: HODOGAYA CHEMICAL CO., LTD., Tokyo (JP)

(21) Appl. No.: 18/289,826

(22) PCT Filed: May 18, 2022
(86) PCT No.: PCT/JP2022/020741

§ 371 Date: Nov. 7, 2023

(30) Foreign Application Priority Data
May 21, 2021 (JP) 2021-086023

(51) Int. Cl. H10K 50/11; C08G 61/12; H10K 50/15; H10K 50/18; H10K 85/10

(52) U.S. Cl. CPC H10K 50/11; C08G 61/12; H10K 50/15; H10K 50/181; H10K 85/111

(57) ABSTRACT

An objective of the invention is to provide a high molecular weight material having excellent hole injectability and transportability, electron blockability, and high stability in a thin-film state. Another objective is to provide an organic EL device including an organic layer (thin film) formed by the high molecular weight material and having high luminous efficiency and long lifetime. The invention relates to a high molecular weight compound including a repeating unit represented by general formula (1) and a repeating unit represented by general formula (2), and having a weight-average molecular weight of 10,000 or greater to less than 1,000,000 in terms of polystyrene.

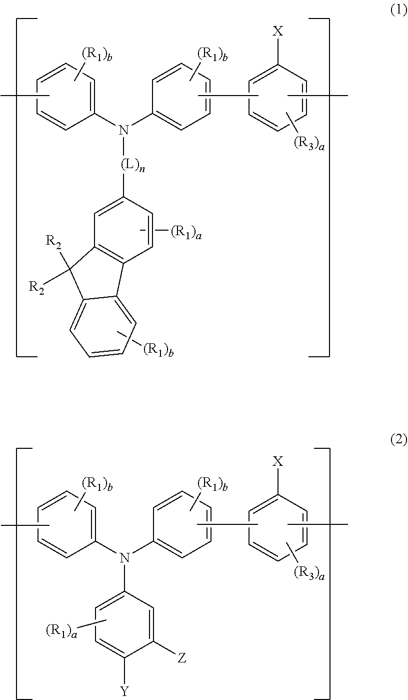

### TECHNICAL FIELD

The present invention relates to high molecular weight compounds suitable for organic electroluminescent devices (organic EL devices) which are self-emissive devices suitably used in various types of display apparatuses, and to such devices.

### BACKGROUND ART

Organic EL devices are self-emissive devices, and are therefore brighter, have better visibility, and are capable of clearer display compared to liquid crystal devices. Hence, active studies have been carried out on organic EL devices.

An organic EL device is constituted by interposing a thin film (organic layer) made of an organic compound between an anode and a cathode. Thin film formation methods are broadly categorized into the vacuum deposition method and the coating method. The vacuum deposition method is a technique in which a thin film is formed on a substrate in vacuum mainly using a low molecular weight compound, and this technique is already in practical use. The coating method, on the other hand, is a technique in which a thin film is formed on a substrate through ink-jetting, printing, etc., using a solution composed mainly of a high molecular weight compound. The coating method has high material usage efficiency and is suitable for area enlargement and resolution enhancement, and is therefore an essential technique for future large-area organic EL displays.

The vacuum deposition method employing low molecular weight materials suffers from extremely low material usage efficiency. Also, upsizing may increase shadow mask warpage, thus posing difficulty in uniform deposition onto large substrates. This technique also suffers from high manufacturing costs.

In contrast, with high molecular weight materials, a uniform film can be formed even on a large substrate by applying a solution prepared by dissolving the material in an organic solvent. Thus, high molecular weight materials can be used for coating methods, typified by ink-jetting and printing. In this way, material usage efficiency can be improved, and device manufacturing cost can therefore be significantly reduced.

Various studies have been conducted heretofore regarding organic EL devices employing high molecular weight materials, but device properties, such as luminous efficiency and longevity, are not necessarily sufficient (for example, see Patent Literatures 1 to 5).

Meanwhile, a fluorene polymer called “TFB” has been known as a hole-transporting material typically used heretofore in high molecular weight organic EL devices (see Patent Literatures 6 and 7). Unfortunately, TFB has insufficient hole transportability as well as insufficient electron blockability, which causes portions of electrons to pass through the light-emitting layer, therefore making it impossible to expect improvements in luminous efficiency. Also, film adhesiveness with adjacent layers is poor, therefore making it impossible to expect long device life.

### CITATION LIST

### Patent Literature

### Patent Literature 1: Japanese Unexamined Patent Publication No. 2005-272834

### Patent Literature 2: Japanese Unexamined Patent Publication No. 2007-119763

### Patent Literature 3: Japanese Unexamined Patent Publication No. 2007-162009

### Patent Literature 4: Japanese Unexamined Patent Publication No. 2007-177225

Patent Literature 5; U.S. Pat. No. 7,651,746 B2

### Patent Literature 6: International Publication No. 1999/054385

### Patent Literature 7: International Publication No. 2005/059951

### SUMMARY OF INVENTION

An objective of the invention is to provide a high molecular weight material having excellent hole injectability and transportability, electron blockability, and high stability in a thin-film state. Another objective is to provide an organic EL device including an organic layer (thin film) formed by the high molecular weight material and having high luminous efficiency and long lifetime.

Inventors focused on the fact that high molecular weight compounds that include a repeating unit having a fluorene-structure-containing triarylamine structure have high hole injectability and transportability and can be expected to achieve a wide bandgap, and thus accomplished the present invention as a result of synthesizing and studying high molecular weight compounds including various repeating units having triarylamine structures (referred to hereinafter as “triarylamine repeating units”).

More specifically, the present invention is as described below.

{1}

A high molecular weight compound including a repeating unit represented by general formula (1) below and a repeating unit represented by general formula (2) below, and having a weight-average molecular weight of 10,000 or greater to less than 1,000,000 in terms of polystyrene.

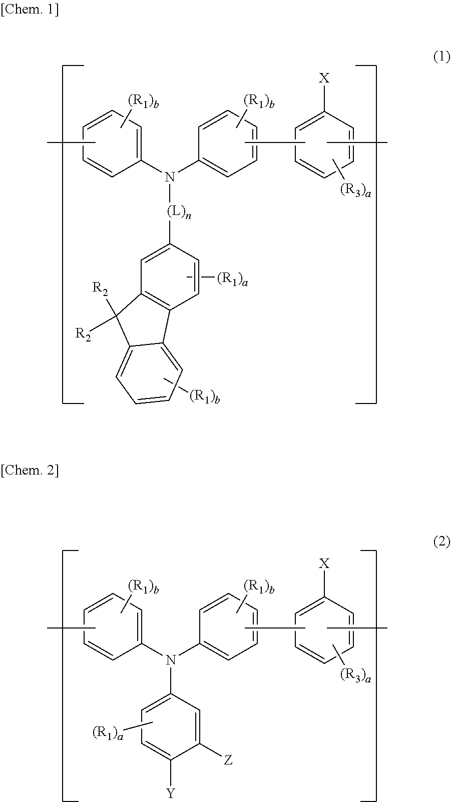

In the formulas:
R₁ and R₃ may be the same or different from one another, and each represent a deuterium atom, a cyano group, a nitro group, a halogen atom, an alkyl group having 40 or fewer carbon atoms, a cycloalkyl group having 40 or fewer carbon atoms, an alkyloxy group having 40 or fewer carbon atoms, a cycloalkyloxy group having 40 or fewer carbon atoms, an alkenyl group having 40 or fewer carbon atoms, or an aryloxy group having 40 or fewer carbon atoms;
R₁ in general formula (1) and R₁ in general formula (2) may be the same or different from one another, and R₁ in general formula (1) and R₁ in general formula (2) represent the same group;
a represents an integer from 0 to 3, and b represents an integer from 0 to 4;
R₂ represents an alkyl group having 3 to 40 carbon atoms, a cycloalkyl group having 3 to 40 carbon atoms, or an alkyloxy group having 3 to 40 carbon atoms;
L represents a phenylene group, and n represents an integer from 0 to 3;
X represents a hydrogen atom, an amino group, a monovalent aryl group, or a monovalent heteroaryl group;
X in general formula (1) and X in general formula (2) represent the same group; and
Y and Z may be the same or different from one another, and each represent a hydrogen atom, a monovalent aryl group, or a monovalent heteroaryl group.

{2}

The high molecular weight compound as set forth in clause {1}, wherein, in the general formulas (1) and (2), a and b are 0.

{3 }

The high molecular weight compound as set forth in clause {1} or {2}, wherein, in the general formula (1), R₂ is an alkyl group having 3 to 40 carbon atoms.

{4}

The high molecular weight compound as set forth in any one of clauses {1 } to {3}, wherein, in the general formulas (1) and (2), X is a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

{5}

The high molecular weight compound as set forth in clause {1 }, including a repeating unit represented by general formula (3) below and including a thermally cross-linkable structural unit Q.

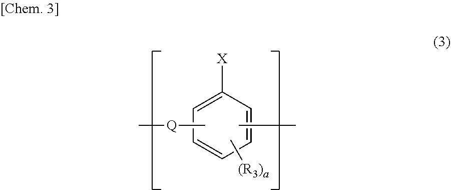

In the formula, R₃, X, and a are all the same as those described in general formula (1).

{6}

The high molecular weight compound as set forth in clause {5}, wherein the thermally cross-linkable structural unit Q is a structural unit represented by general formulas (4a) to (4z) as shown in FIGS. 10 and 11.

{7}

An organic electroluminescent device including a pair of electrodes, and an organic layer interposed between the electrodes, wherein the organic layer comprises, as a constituent material, the high molecular weight compound as set forth in any one of clauses {1} to {6}.

{8}

The organic electroluminescent device as set forth in clause {7}, wherein the organic laver is a hole transport laver.

{9}

The organic electroluminescent device as set forth in clause {7}, wherein the organic layer is an electron blocking layer.

{10}

The organic electroluminescent device as set forth in clause {7}, wherein the organic layer is a hole injection layer.

{11}

The organic electroluninescent device as set forth in clause {7}, wherein the organic layer is a light-emitting layer.

The aforementioned high molecular weight compound of the present invention has a weight-average molecular weight within the range of 10,000 or greater to less than 1,000,000 in terms of polystyrene as measured by gel permeation chromatography (GPC).

A high molecular weight compound of the present invention has such characteristics as:
(1) excellent hole injection properties;
(2) high hole mobility; and
(3) wide bandgap and excellent electron blockability.

An organic layer formed by a high molecular weight compound of the present invention can suitably be used as a hole transport layer, an electron blocking layer, a hole injection layer, or a light-emitting layer. An organic EL device formed by interposing the organic layer between a pair of electrodes has such advantages as:
(1) high luminous efficiency and power efficiency:
(2) low practical driving voltage; and
(3) long lifetime.

### BRIEF DESCRIPTION OF DRAWINGS

FIG. 1 illustrates chemical structures of structural units 1-1 to 1-6 suitable as a repeating unit represented by general formula (1).

FIG. 2 illustrates chemical structures of structural units 1-7 to 1-12 suitable as a repeating unit represented by general formula (1).

FIG. 3 illustrates chemical structures of structural units 1-13 to 1-20 suitable as a repeating unit represented by general formula (1).

FIG. 4 illustrates chemical structures of structural units 1-21 to 1-28 suitable as a repeating unit represented by general formula (1).

FIG. 5 illustrates chemical structures of structural units 2-1 to 2-9 suitable as a repeating unit represented by general formula (2).

FIG. 6 illustrates chemical structures of structural units 2-10 to 2-21 suitable as a repeating unit represented by general formula (2).

FIG. 7 illustrates chemical structures of structural units 2-22 to 2-33 suitable as a repeating unit represented by general formula (2).

FIG. 8 illustrates chemical structures of structural units 2-34 to 2-48 suitable as a repeating unit represented by general formula (2).

FIG. 9 illustrates chemical structures of structural units 2-49 to 2-58 suitable as a repeating unit represented by general formula (2).

FIG. 10 illustrates chemical structures of structural units (4a) to (4p) as thermally cross-linkable structural unit Q.

FIG. 11 illustrates chemical structures of structural units (4q) to (4z) as thermally cross-linkable structural unit Q.

FIG. 12 illustrates chemical structures of substituents 1 to 24 suitable as substituent X in general formulas (1) to (3).

FIG. 13 illustrates chemical structures of substituents 25 to 44 suitable as substituent X in general formulas (1) to (3).

FIG. 14 illustrates an example of a layer configuration of an organic EL device of the present invention.

FIG. 15 illustrates an example of a layer configuration of an organic EL device of the present invention.

FIG. 16 is a ¹H-NMR chart of High molecular weight compound I of Example 1.

FIG. 17 is a ¹H-NMR chart of High molecular weight compound II of Example 2.

FIG. 18 is a ¹H-NMR chart of High molecular weight compound III of Example 3.

FIG. 19 is a ¹H-NMR chart of High molecular weight compound IV of Example 4.

FIG. 20 is a ¹H-NMR chart of High molecular weight compound V of Example 5.

FIG. 21 is a ¹H-NMR chart of High molecular weight compound VI of Example 6.

FIG. 22 is a ¹H-NMR chart of High molecular weight compound VII of Example 7.

FIG. 23 is a ¹H-NMR chart of High molecular weight compound VIII of Example 8.

FIG. 24 is a ¹H-NMR chart of High molecular weight compound IX of Example 9.

FIG. 25 is a ¹H-NMR chart of High molecular weight compound X of Example 10.

FIG. 26 is a ¹H-NMR chart of High molecular weight compound XI of Example 11.

### DESCRIPTION OF EMBODIMENTS

### <Triarylamine Repeating Unit>

The two types of triarylamine repeating units included in a high molecular weight compound of the present invention are structures represented by the following general formulas (1) and (2).

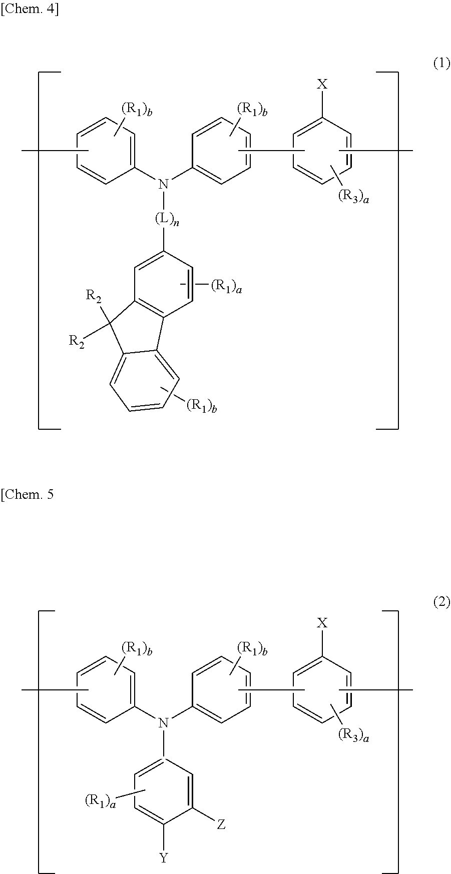

In the general formulas (1) and (2). R₁ and R₃ may be the same or different from one another, and each represent a deuterium atom; a cyano group; a nitro group; a halogen atom such as a fluorine atom, a chlorine atom, a bromine atom, or an iodine atom; or an alkyl group, a cycloalkyl group, an alkyloxy group, a cycloalkyloxy group, an alkenyl group or an aryloxy group each having 40 or fewer carbon atoms.

From the viewpoint of excellent hole injectability and transportability, it is preferable that R₁ and R₃ are an alkyl group or an alkyloxy group having 1 to 8 carbon atoms, a cycloalkyl group or a cycloalkyloxy group having 5 to 10 carbon atoms, an alkenyl group having 2 to 6 carbon atoms, or an aryloxy group.

Examples of the aforementioned alkyl groups, alkyloxy groups, cycloalkyl groups, cycloalkyloxy groups, alkenyl groups, and aryloxy groups may include the following groups.

Alkyl groups (carbon atoms: 1 to 8):

Methyl group, ethyl group, n-propyl group, isopropyl group, n-butyl group, isobutyl group, tert-butyl group, n-pentyl group, isopentyl group, neopentyl group, n-hexyl group, isohexyl group, neohexyl group, n-heptyl group, isoheptyl group, neoheptyl group, n-octyl group, isooctyl group, neooctyl group, etc.

Alkyloxy groups (carbon atoms: 1 to 8):

Methyloxy group, ethyloxy group, n-propyloxy group, isopropyloxy group, n-butyloxy group, tert-butyloxy group, n-pentyloxy group, n-hexyloxy group, n-heptyloxy group, n-octyloxy group, etc.

Cycloalkyl groups (carbon atoms: 5 to 10):

Cyclopentyl group, cyclohexyl group, 1-adamantyl group, 2-adamantyl group, etc.

Cycloalkyloxy groups (carbon atoms: 5 to 10):

Cyclopentyloxy group, cyclohexyloxy group, cycloheptyloxy group, cyclooctyloxy group, 1-adamantyloxy group, 2-adamantyloxy group, etc.

Alkenyl groups (carbon atoms: 2 to 6):

Vinyl group, allyl group, isopropenyl group, 2-butenyl group, etc.

### Aryloxy Groups:

Phenyloxy group, tolyloxy group, etc.

In the general formulas (1) and (2), a represents an integer from 0 to 3, and b represents an integer from 0 to 4.

In the high molecular weight compound of the present invention, it is preferable that, in terms of synthesis, the aforementioned a and b are 0.

In the general formula (1), R₂ represents an alkyl group, a cycloalkyl group or an alkyloxy group each having 3 to 40 carbon atoms.

From the viewpoint of excellent hole injectability and transportability, it is preferable that R₂ is an alkyl group or an alkyloxy group having 1 to 8 carbon atoms, or a cycloalkyl group or a cycloalkyloxy group having 5 to 10 carbon atoms.

Examples of alkyl groups, alkyloxy groups, cycloalkyl groups, and cycloalkyloxy groups represented by R₂ may include the same groups as described in R₁, and R₃.

In the high molecular weight compound of the present invention, from the viewpoint of improving solubility to an organic solvent, it is most preferable that the aforementioned R₂ is a n-hexyl group or a n-octyl group.

In the general formulas (1) and (2), substituent X represents a hydrogen atom, an amino group, a monovalent aryl group, or a monovalent heteroaryl group.

Examples of monovalent aryl groups and monovalent heteroaryl groups represented by X may include the following groups.

### Aryl Groups:

Phenyl group, naphthyl group, anthracenyl group, phenanthrenyl group, fluorenyl group, indenyl group, pyrenyl group, perylenyl group, fluoranthenyl group, etc.

### Heteroaryl Groups:

Pyridyl group, pyrimidinyl group, triazinyl group, furyl group, pyrrolyl group, thienyl group, quinolyl group, isoquinolyl group, benzofuranyl group, benzothienyl group, indolyl group, carbazolyl group, indenocarbazolyl group, benzooxazolyl group, benzothiazolyl group, quinoxalinyl group, benzoimidazolyl group, pyrazolyl group, dibenzofuranyl group, dibenzothienyl group, naphthyridinyl group, phenanthrolinyl group, acridinyl group, carbolinyl group, etc.

The aforementioned amino groups, aryl groups, and heteroaryl groups may optionally have a substituent. Examples of substituents may include the following groups, in addition to deuterium atoms, cyano groups, nitro groups, etc.:
halogen atoms, such as fluorine, chlorine, bromine, and iodine;
alkyl groups, particularly groups having 1 to 8 carbon atoms, such as the methyl group, ethyl group, n-propyl group, isopropyl group, n-butyl group, isobutyl group, tert-butyl group, n-pentyl group, isopentyl group, neopentyl group, n-hexyl group, isohexyl group, neohexyl group, n-heptyl group, isoheptyl group, neoheptyl group, n-octyl group, isooctyl group, neooctyl group, etc.;
alkyloxy groups, particularly groups having 1 to 8 carbon atoms, such as the methyloxy group, ethyloxy group, propyloxy group, etc.;
alkenyl groups, such as the vinyl group, allyl group, etc.:
aryloxy groups, such as the phenyloxy group, tolyloxy group, etc.:
aryl groups, such as the phenyl group, biphenylyl group, terphenylyl group, naphthyl group, anthracenyl group, phenanthrenyl group, fluorenyl group, indenyl group, pyrenyl group, perylenyl group, fluoranthenyl group, triphenylenyl group, etc.; heteroaryl groups, such as the pyridyl group, pyrimidinyl group, triazinyl group, thienyl group, furyl group, pyrrolyl group, quinolyl group, isoquinolyl group, benzofuranyl group, benzothienyl group, indolyl group, carbazolyl group, indenocarbazolyl group, benzooxazolyl group, benzothiazolyl group, quinoxalinyl group, benzoimidazolyl group, pyrazolyl group, dibenzofuranyl group, dibenzothienyl group, carbolinyl group, etc.;
arylvinyl groups, such as the styryl group, naphthylvinyl group, etc.; and
acyl groups, such as the acetyl group, benzoyl group, etc.

These substituents may further include any of the substituents given as examples above.

Further, it is preferable that these substituents are each present independently, but the substituents may be bonded to each other via a single bond, a methylene group optionally having a substituent, an oxygen atom, or a sulfur atom, to form a ring.

For example, the aforementioned aryl groups and heteroaryl groups may have a phenyl group as a substituent, and this phenyl group may further have a phenyl group as a substituent. Stated differently, taking an aryl group as an example, the aryl group may be a biphenylyl group, a terphenylyl group, or a triphenylenyl group.

From the viewpoint of excellent hole injectability and transportability, it is preferable that the substituent X in the general formulas (1) and (2) is a hydrogen atom, a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

In the general formula (1), L represents a phenylene group, and n represents an integer from 0 to 3.

The aforementioned L may optionally have a substituent. Examples of such substituents may include the same groups as the substituents that may substitute the aforementioned substituent X. and these substituents may further optionally have a substituent.

In the general formulas (1) and (2), Y and Z represent a hydrogen atom, a monovalent aryl group, or a monovalent heteroaryl group.

Examples of the monovalent aryl group and the monovalent heteroaryl group represented by Y and Z may include the same groups as those described in X.

It is preferable that at least one of Y and Z is a monovalent aryl group, and more preferably, at least Y is a monovalent aryl group.

From the viewpoint of excellent hole injectability and transportability, it is preferable that the monovalent aryl group represented by Y and Z is a phenyl group, a naphthyl group, a phenanthrenyl group, a biphenyl group, a naphthylphenyl group, or a (triphenyl)phenyl group.

The monovalent aryl group or the monovalent heteroaryl group represented by Y and Z may optionally have a substituent (for example, a phenyl group) as described in X.

Further, Y and Z may be bonded to each other via a single bond, a methylene group optionally having a substituent, an oxygen atom, or a sulfur atom, to form a ring.

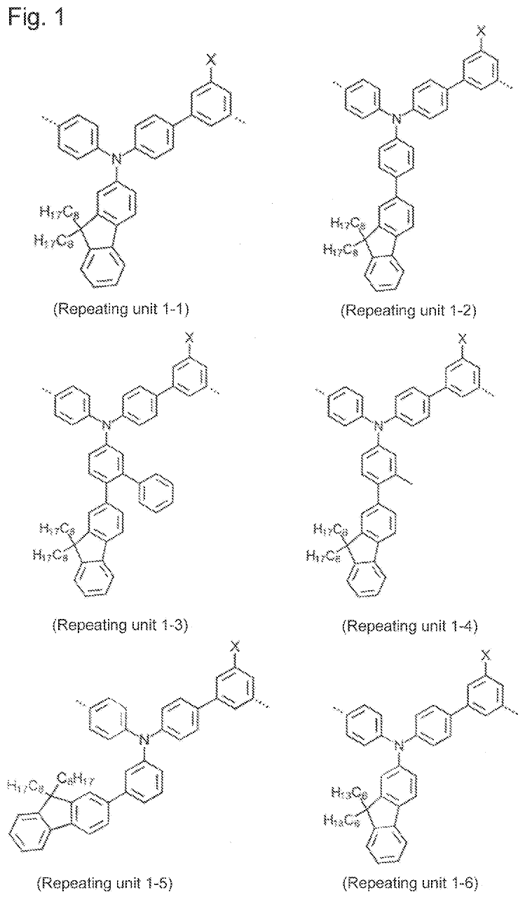

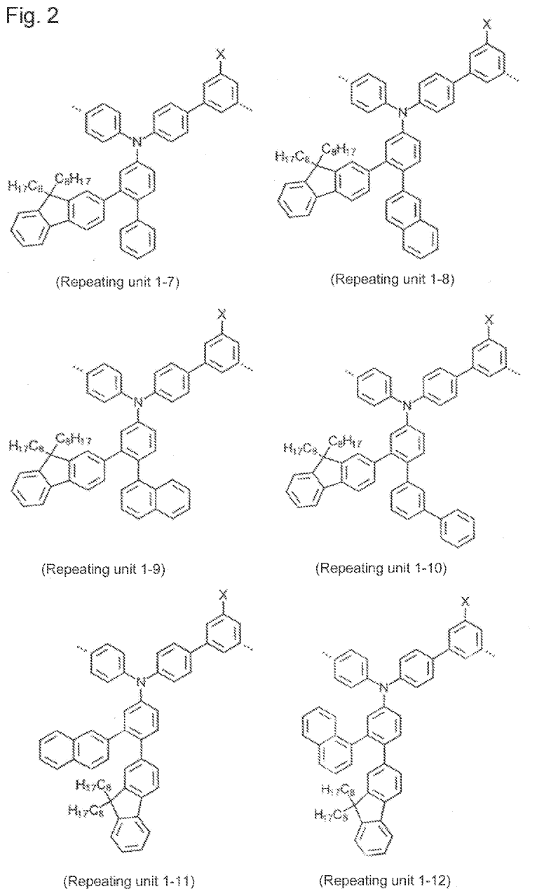

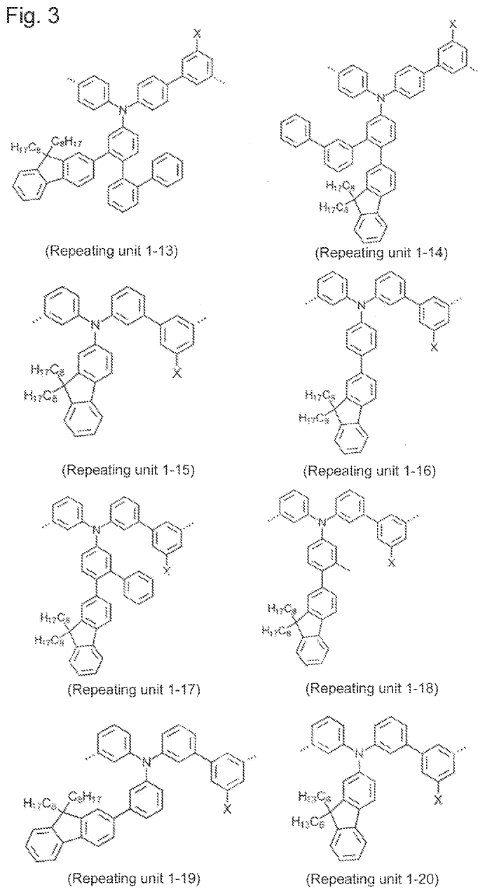

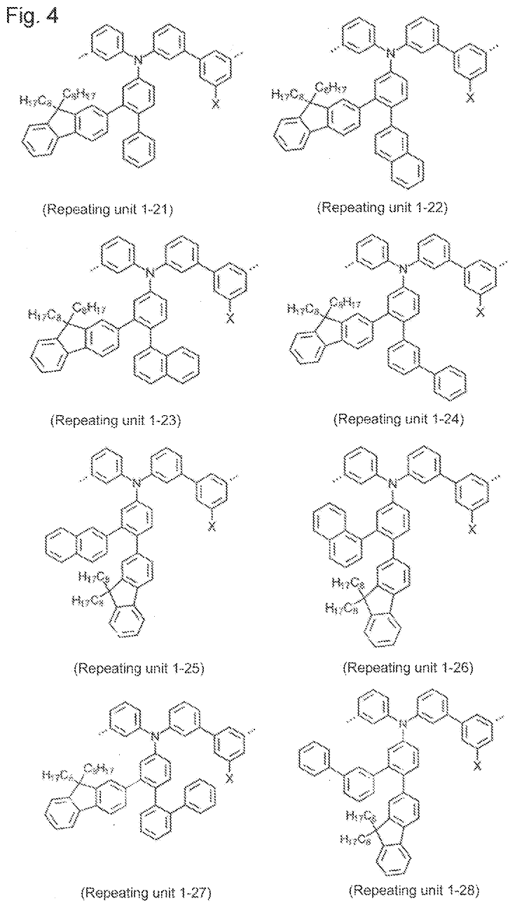

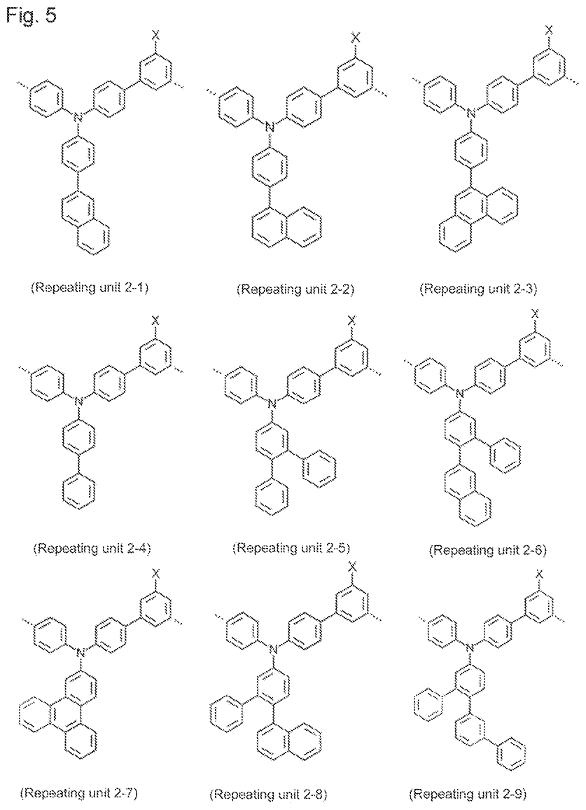

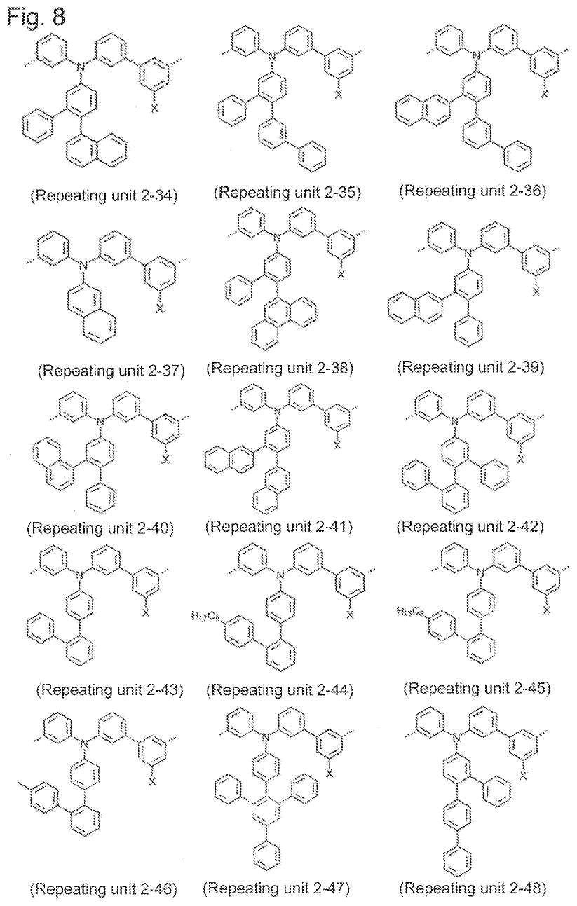

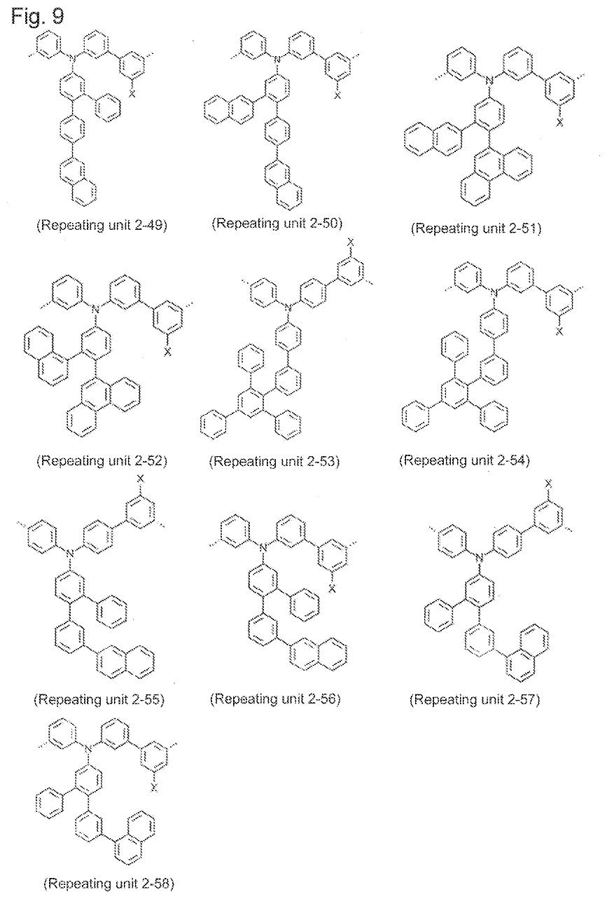

Concrete examples of repeating units represented by the general formula (1) in the present invention are shown as repeating units 1-1 to 1-28 in FIGS. 1 to 4. Further, concrete examples of repeating units represented by the general formula (2) are shown as repeating units 2-1 to 2-58 in FIGS. 5 to 9. Note that, in the chemical formulas shown in FIGS. 1 to 9, a broken line represents a bonding site to an adjacent repeating unit, and a solid line with a free end extending from a ring indicates that the free end is a methyl group. Although preferable concrete examples of repeating units are shown, the repeating units that may be used in the present invention are not limited to these examples.

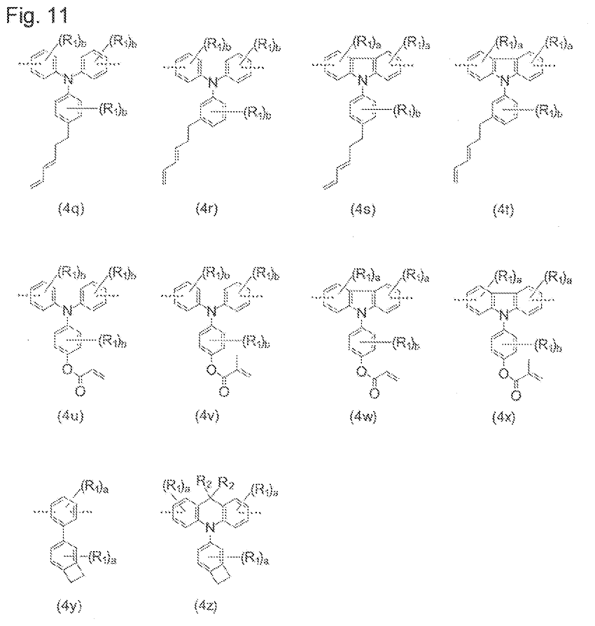

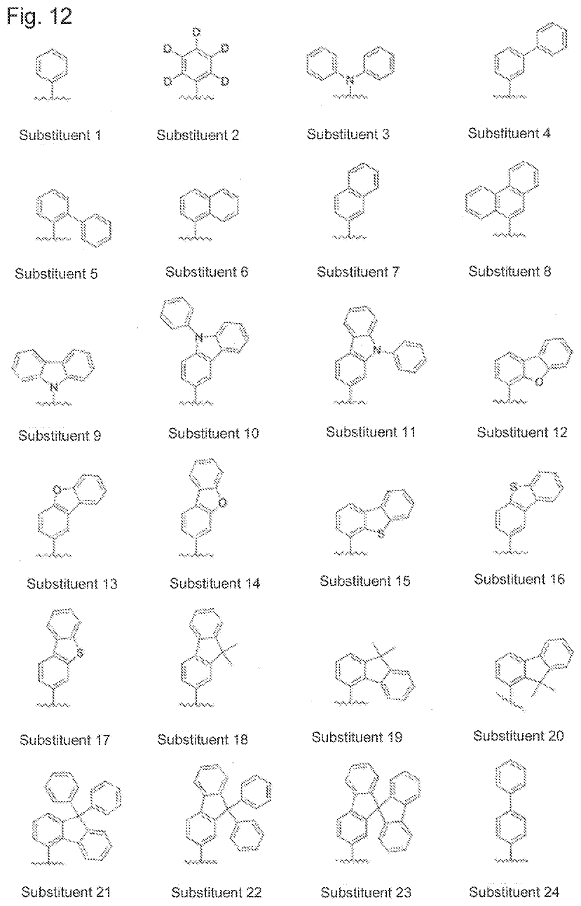

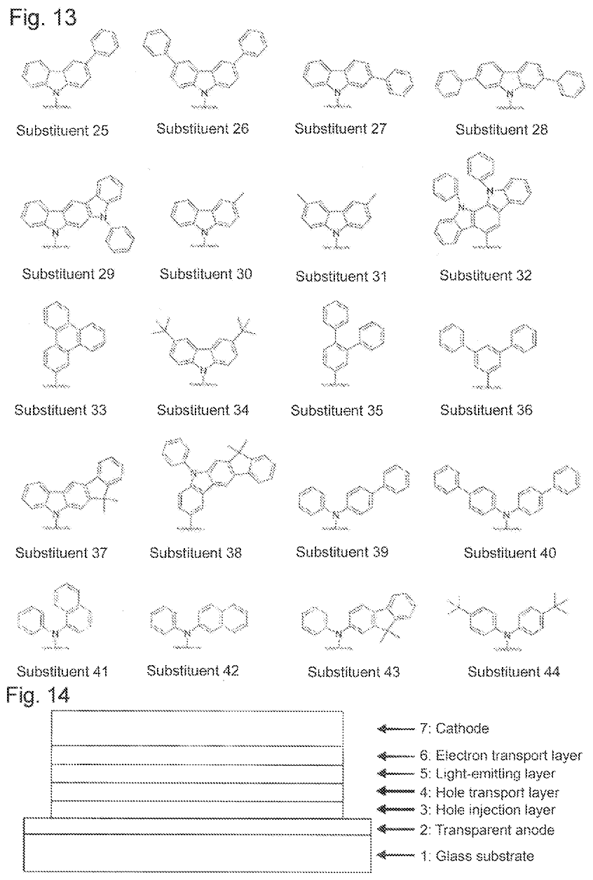

Concrete examples of substituents X in the general formulas (1) to (3) in the present invention are shown as substituents 1 to 44 in FIGS. 12 and 13. Note that, in the chemical formulas shown in FIGS. 12 and 13, a wavy line represents a bonding site. Although preferable concrete examples of substituents X are shown in the figures, the substituent X in the present invention is not limited to these examples.

### <High Molecular Weight Compound>

From the viewpoint of further improving properties, such as hole injection properties, hole mobility, electron blockability, thin-film stability, heat resistance, etc., and also ensuring film formability, the high molecular weight compound of the present invention, which is constituted by a repeating unit represented by the general formula (1) and a repeating unit represented by the general formula (2), has, for example, a weight-average molecular weight ranging from 10,000 or greater to less than 1,000,000, more preferably from 10,000 or greater to less than 500,000, even more preferably from 10,000 or greater to less than 300,000, in terms of polystyrene as measured by GPC.

In order to improve stability in a thin-film state, it is preferable that the high molecular weight compound of the present invention includes a repeating unit represented by the following general formula (3) and including a thermally cross-linkable structural unit Q.

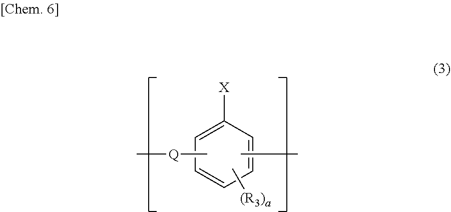

In the general formula (3), R₃, X, and a are all the same as those described in general formula (1).

The thermally cross-linkable structural unit Q is a structural unit including a thermally cross-linkable functional group. Examples of the thermally cross-linkable functional group may include a vinyl group, an ethynyl group, an acryloyl group, a methacryloyl group, a conjugated diene, a cyclobutane ring, etc.

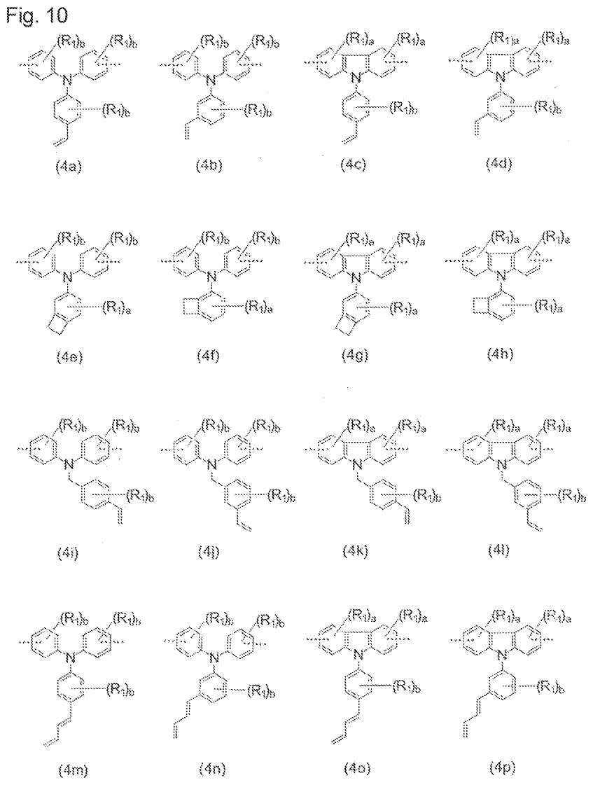

Concrete examples of the thermally cross-linkable structural unit Q are illustrated as general formulas (4a) to (4z) in FIGS. 10 and 11.

Note that, in the general formulas (4a) to (4z), a broken line represents a bonding site to an adjacent structural unit, whereas a solid line with a free end extending from a ring indicates that the free end is a methyl group.

In the general formulas (4a) to (4z), R₁, R₂, a, and b are all the same as those described in general formula (1).

In the high molecular weight compound of the present invention, when the repeating unit represented by general formula (1) is defined as A, the repeating unit represented by general formula (2) is defined as B, and the repeating unit represented by general formula (3) is defined as C, it is preferable that the content of the repeating unit A in the total of the repeating units is 1 mol % or greater, particularly 30 mol % or greater. On condition that the content of the repeating unit A is within the above range, it is preferable that the content of the repeating unit B is preferably 1 mol % or greater, particularly 10 to 60 mol %, and the content of the repeating unit C is preferably 1 mol % or greater, particularly 10 to 20 mol %. A high molecular weight compound containing the repeating units A, B and C in amounts satisfying the aforementioned conditions is most preferable in terms of forming an organic layer of the organic EL device.

The high molecular weight compound of the present invention can be synthesized by connecting the structural units by forming C—C bonds or C—N bonds through the Suzuki polymerization reaction or the Hartwig-Buchwald polymerization reaction. More specifically, the high molecular weight compound of the present invention can be synthesized by preparing unit compounds that respectively have the aforementioned structural units, and subjecting the unit compounds to boric acid esterification or halogenation as appropriate and then to a polycondensation reaction using a catalyst.

For example, a high molecular weight compound including 30 mol % of repeating unit A represented by general formula (1), 60 mol % of repeating unit B represented by general formula (2), and 10 mol % of repeating unit C for improving thermal cross-linkability is represented by general formula (5) below.

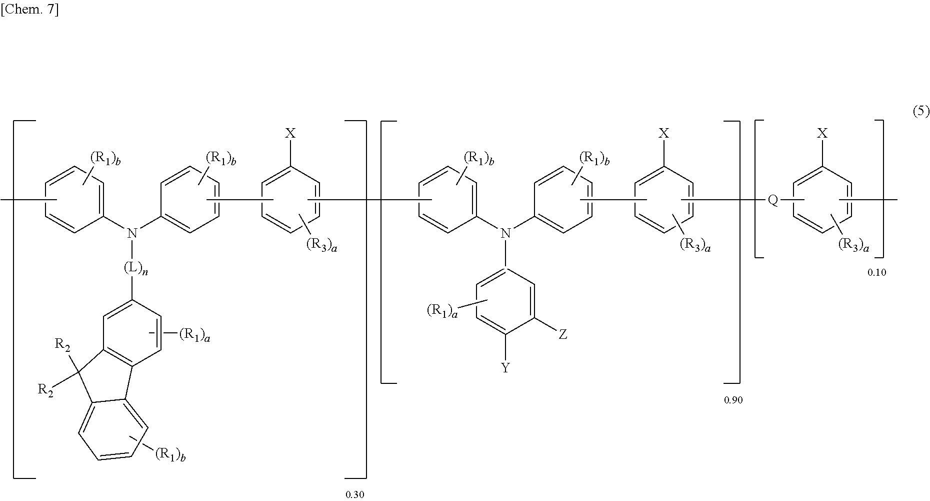

The aforementioned high molecular weight compound of the present invention can be dissolved in an aromatic organic solvent, such as benzene, toluene, xylene, anisole, etc., to prepare a coating liquid, and the coating liquid can be coated onto a predetermined substrate and then heated and dried, to thereby form a thin film having excellent properties such as hole injectability, hole transportability, electron blockability, etc. The obtained thin film also has excellent heat resistance and excellent adhesiveness to other layers.

The high molecular weight compound can be used as a constituent material for a hole injection layer and/or a hole transport layer of an organic EL device. A hole injection layer and a hole transport layer formed by the high molecular weight compound have higher hole injectability, greater mobility and higher electron blockability compared to layers formed by conventional materials, and can confine excitons generated within the light-emitting layer. It is also possible to achieve such advantages as increasing the probability of hole-electron recombination and achieving high luminous efficiency, as well as lowering the driving voltage and improving the organic EL device's durability.

Further, the high molecular weight compound of the present invention having the aforementioned electric properties has a wider bandgap than conventional materials and is effective for confining excitons, and can therefore be suitably used also for electron blocking layers and light-emitting layers, as a matter of course.

### <Organic EL Device>

An organic EL device according to the present invention including an organic layer formed using the aforementioned high molecular weight compound of the present invention includes a pair of electrodes and at least one layer of an organic layer interposed therebetween, and may have, for example, a structure as illustrated in FIG. 14. More specifically, a transparent anode 2, a hole injection layer 3, a hole transport layer 4, a light-emitting layer 5, an electron transport layer 6, and a cathode 7 are provided on a glass substrate 1 (or a transparent substrate other than glass, such as a transparent resin substrate).

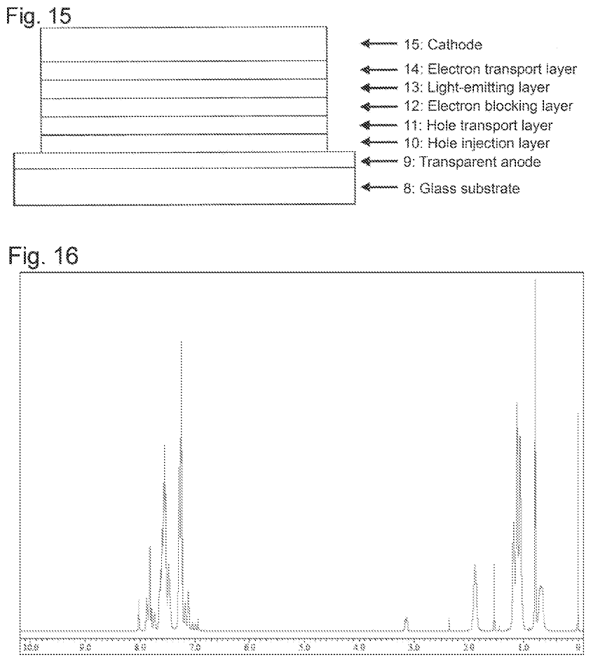

Needless to say, the organic EL device of the present invention is not limited to the aforementioned layer structure; for example, a hole blocking layer may be provided between the light-emitting layer 5 and the electron transport layer 6, or an electron blocking layer may be provided between a hole transport layer 4 and a light-emitting layer 5 as in the structure illustrated in FIG. 15, or an electron injection layer may be provided between a cathode 7 and an electron transport layer 6. Also, some layers may be omitted. For example, a simple layer structure may be created in which an anode 2, a hole transport layer 4, a light-emitting layer 5, an electron transport layer 6, and a cathode 7 are provided on a glass substrate 1. Moreover, a two-layer structure, created by stacking two layers having the same functionality, is also possible.

By making use of such properties as hole injectability, hole transportability, etc., the high molecular weight compound of the present invention can suitably be used as a material for forming an organic layer, such as a hole injection layer 3, a hole transport layer 4, a light-emitting layer 5, or an electron blocking layer, provided between the aforementioned anode 2 and cathode 7.

In the organic EL device, the transparent anode 2 may be formed by a known electrode material, and may be formed by evaporatively depositing an electrode material having a large work function, such as ITO, gold, etc., onto a glass substrate 1 (or a transparent substrate).

The hole injection layer 3 provided on the transparent anode 2 can be formed, for example, by using a coating liquid in which the high molecular weight compound of the present invention is dissolved in an aromatic organic solvent such as toluene, xylene, anisole, etc. More specifically, this coating liquid can be coated onto the transparent anode 2 by spin coating, ink-jetting, etc., to form the hole injection layer 3.

Further, in the organic EL device of the present invention, the hole injection layer 3 may be formed by using a conventionally known material, such as one or more of the following materials, without using the high molecular weight compound of the present invention:
porphyrin compounds typified by copper phthalocyanine,
starburst-type triphenylamine derivatives;
arylamines (for example, triphenylamine trimer and tetramer) having a structure connected by a single bond or a divalent group that does not include a hetero atom:
acceptor heterocyclic compounds such as hexacyanoazatriphenylene; and
coating-type high molecular weight materials, such as poly(3,4-ethylene dioxythiophene) (PEDOT), poly(styrene sulfonate) (PSS), etc.

Formation of a layer (thin film) using such materials can be achieved, for example, by vapor deposition or by coating, such as spin coating, ink-jetting, etc. This is the same for the other layers, and film formation is conducted by vapor deposition or coating, depending on the type of film-forming material.

Like the hole injection layer 3, the hole transport layer 4 provided on the hole injection layer 3 can be formed by coating, such as spin coating, ink-jetting, etc., using a coating liquid in which the high molecular weight compound of the present invention has been dissolved in an organic solvent.

In the organic EL device including an organic layer formed using the high molecular weight compound of the present invention, the hole transport layer 4 can be formed by using a conventionally known hole-transporting material. Typical examples of such hole-transporting materials may include the following.

Benzidine derivatives, such as:
N,N′-diphenyl-N,N′-di(m-tolyl)benzidine (abbreviated hereinbelow as “TPD”);
N,N′-diphenyl-N,N′-di(α-naphthyl)benzidine (abbreviated hereinbelow as “NPD”); and
N,N,N′,N′-tetrabiphenylylbenzidine.
   Amine-based derivatives, such as:
1,1-bis[4-(di-4-tolylamino)phenyl]cyclohexane (abbreviated hereinbelow as “TAPC”); and
various triphenylamine trimers and tetramers.

Coating-type high molecular weight materials that may also be used for hole injection layers.

The aforementioned material(s) for the hole transport layer, including the high molecular weight compound of the present invention, may be formed into a film singly, or two or more types may be mixed and formed into a film. One or more types of the aforementioned compounds may be used to form a plurality of layers, and a multilayer film formed by stacking such layers may constitute the hole transport layer.

Further, in the organic EL device of the present invention illustrated in FIG. 14, the hole injection layer 3 and the hole transport layer 4 may be made into a single hole injection-transport layer having functions of both the layers. Such a hole injection-transport layer can be formed by coating using a polymer material such as PEDOT etc.

In the hole transport layer 4 (same for the hole injection layer 3), it is possible to use, for example, a material ordinarily used for such layers and p-doped with trisbromophenylamine hexachloroantimonate or a radialene derivative (see, for example, WO2014/009310). The hole transport layer 4 (or the hole injection layer 3) may be formed by using a polymer compound having a TPD basic skeleton.

Furthermore, as illustrated in FIG. 15, an electron blocking layer 12 can be provided between the hole transport layer 1I and the light-emitting layer 13. The electron blocking layer 12 can be formed by coating, such as spin coating, ink-jetting, etc., by using a coating liquid in which the high molecular weight compound of the present invention has been dissolved in an organic solvent.

Further, in the organic EL device of the present invention, the electron blocking layer can be formed by using a known electron blocking compound having electron blockability, such as a carbazole derivative or a compound having a triphenylsilyl group and a triarylamine structure. Concrete examples of carbazole derivatives and compounds having a triarylamine structure may include the following.

### Examples of Carbazole Derivatives

4,4′,4″-tri(N-carbazolyl)triphenylamine (abbreviated hereinbelow as “TCTA”);
9,9-bis[4-(carbazol-9-yl)phenyl]fluorene;
1,3-bis(carbazol-9-yl)benzene (abbreviated hereinbelow as “mCP”); and
2,2-bis(4-carbazol-9-ylphenyl)adamantane (abbreviated hereinbelow as “Ad-Cz”).

### Example of Compound Having Triarylamine Structure

9-[4-(carbazol-9-yl)phenyl]-9-[4-(triphenylsilyl)phenyl]-9H-fluorene.

The electron blocking layer, including the high molecular weight compound of the present invention, may be formed into a film singly, or two or more types may be mixed and formed into a film. One or more types of the aforementioned compounds may be used to form a plurality of layers, and a multilayer film formed by stacking such layers may constitute the electron blocking layer.

In the organic EL device of the present invention, the light-emitting layer 5 can be formed by using a light-emitting material, with examples including metal complexes of quinolinol derivatives, such as Alq₃, as well as various other metal complexes of zinc, beryllium, aluminum, etc., anthracene derivatives, bisstyrylbenzene derivatives, pyrene derivatives, oxazole derivatives, poly(para-phenylene vinylene) derivatives, etc.

Further, the light-emitting layer 5 may be constituted by a host material and a dopant material. In this case, for the host material, it is possible to use, for example, a thiazole derivative, a benzimidazole derivative, a polydialkylfluorene derivative, etc., in addition to the aforementioned light-emitting material. Furthermore, it is possible to use the aforementioned high molecular weight compound of the present invention. For the dopant material, it is possible to use, for example, quinacridone, coumarin, rubrene, perylene, a derivative of the above, a benzopyran derivative, a rhodamine derivative, an aminostyryl derivative, etc.

The light-emitting layer 5 may have a single-layer structure using one or more types of light-emitting materials, or may have a multilayer structure formed by stacking a plurality of layers.

Furthermore, the light-emitting layer 5 may be formed by using a phosphorescent material as a light-emitting material. For the phosphorescent material, it is possible to use, for example, a phosphorescent substance such as a metal complex of iridium, platinum, etc. Usable examples may include green phosphorescent substances such as Ir(ppy)₃ etc., blue phosphorescent substances such as FIrpic, FIr6, etc., and red phosphorescent substances such as Btp₂Ir(acac) etc. These phosphorescent materials are used by being doped in a hole-injecting/transporting host material or an electron-transporting host material.

It should be noted that, to avoid concentration quenching, doping of the host material(s) with a phosphorescent material is preferably performed by co-vapor deposition within a range of 1 to 30 wt % with respect to the entire light-emitting layer.

Further, for the light-emitting material, it is possible to use, for example, a material emitting delayed fluorescence, e.g., PIC-TRZ, CC2TA, PXZ-TRZ, a CDCB derivative such as 4CzIPN, etc. (see Appl. Phys. Let., 98, 083302 (2011); Chem. Comumm., 48, 11392 (2012). Nature, 492, 234 (2012)).

By forming the light-emitting layer 5 by making the high molecular weight compound of the present invention support a dopant, e.g., a fluorescent substance, a phosphorescent substance, or a material emitting delayed fluorescence, it is possible to achieve an organic EL device that is reduced in driving voltage and improved in luminous efficiency.

In the organic EL device including an organic layer formed using the high molecular weight compound of the present invention, for the hole-injecting/transporting host material, it is possible to use the high molecular weight compound of the present invention. Other than this, it is also possible to use, for example, a carbazole derivative, such as 4,4′-di(N-carbazolyl)biphenyl (abbreviated hereinbelow as “CBP”), TCTA, mCP, etc.

Further, in the organic EL device including an organic layer formed using the high molecular weight compound of the present invention, for the electron-transporting host material, it is possible to use, for example, p-bis(triphenylsilyl)benzene (abbreviated hereinbelow as “UGH2”), 2,2′,2″-(1,3,5-phenylene)-tris(1-phenyl-1H-benzimidazole) (abbreviated hereinbelow as “TPBI”), etc.

In the organic EL device including an organic layer formed using the high molecular weight compound of the present invention, a hole blocking layer (not illustrated in FIG. 14) to be provided between the light-emitting layer 5 and the electron transport layer 6 can be formed by using a known compound having hole blockability. Examples of known compounds having hole blockability may include the following:
phenanthroline derivatives, such as bathocuproine (abbreviated hereinbelow as “BCP”);
metal complexes of quinolinol derivatives, such as bis(2-methyl-8-quinolinato))-4-phenylphenolato aluminum (Ill) (abbreviated hereinbelow as “BAlq”);
various rare-earth complexes;
triazole derivatives;
triazine derivatives; and
oxadiazole derivatives, etc.

These materials can be used also for forming the electron transport layer 6 described below, and can also be used for forming a hole blocking layer-cum-electron transport layer.

The hole blocking layer may have a single-layer structure or a multilayer stacked structure. Each layer is formed by using one or more types of the aforementioned compounds having hole blockability.

In the organic EL device including an organic layer formed using the high molecular weight compound of the present invention, the electron transport layer 6 can be formed by using a known electron-transporting compound, with examples including metal complexes of quinolinol derivatives, such as Alq₃, BAlq, etc., as well as various other metal complexes, pyridine derivatives, pyrimidine derivatives, triazole derivatives, triazine derivatives, oxadiazole derivatives, thiadiazole derivatives, carbodiimide derivatives, quinoxaline derivatives, phenanthroline derivatives, silole derivatives, benzoimidazole derivatives, etc.

The electron transport layer 6 may have a single-layer structure or a multilayer stacked structure. Each layer is formed by using one or more types of the aforementioned electron-transporting compounds.

Further, in the organic EL device including an organic layer formed using the high molecular weight compound of the present invention, an electron injection laver (not illustrated in FIGS. 14 and 15) to be provided as necessary may be formed by a known compound, with examples including alkali metal salts such as lithium fluoride, cesium fluoride, etc., alkaline-earth metal salts such as magnesium fluoride etc., metal oxides such as aluminum oxide etc., and organic metal complexes such as lithium quinolate etc.

For the cathode 7 of the organic EL device including an organic layer formed using the high molecular weight compound of the present invention, an electrode material having a low work function, such as aluminum etc., or an alloy having an even lower work function, such as magnesium silver alloy, magnesium indium alloy, aluminum magnesium alloy, etc., may be used as an electrode material.

As described above, by forming at least one of the hole injection layer, the hole transport layer, the light-emitting layer, and the electron blocking layer illustrated in FIG. 15 by using the high molecular weight compound of the present invention, it is possible to achieve an organic EL device having high luminous efficiency and power efficiency, low practical driving voltage, low emission start voltage, and extremely good durability. Particularly, this organic EL device is reduced in driving voltage and improved in current resistance, and thereby improved in maximum light emission luminance, while having high luminous efficiency.

### EXAMPLES

The present invention will be described below according to the following experimental examples.

In the following description, a repeating unit, within the high molecular weight compound of the present invention, represented by general formula (1) is described as “repeating unit A”, a repeating unit represented by general formula (2) is described as “repeating unit B”, and a repeating unit represented by general formula (3), which is introduced to improve thermal cross-linkability, is described as “repeating unit C”.

Purification of synthesized compounds was conducted by column chromatography purification or crystallization using a solvent. Compound identification was conducted by NMR analysis.

In order to produce high molecular weight compounds of the present invention, the following Intermediates 1 to 10 were synthesized.

### Synthesis of Intermediate 1

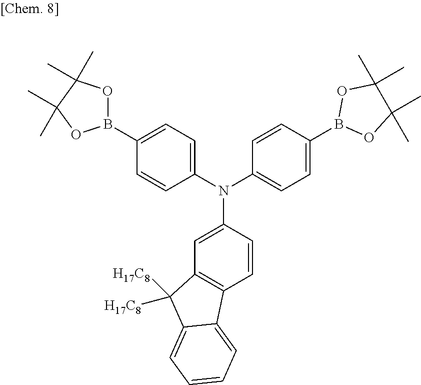

### Intermediate 1

Intermediate 1 is used to introduce a partial structure of Structural unit 1-1 which is a repeating unit shown in FIG. 1.

The following components were placed in a nitrogen-purged reaction vessel, and aerated with nitrogen gas for 30 minutes.
N,N-bis(4-bromophenyl)-9,9-di-n-octyl-9H-fluorene-2-amine: 16.7 g
Bis(pinacolato)diboron: 11.9 g
Potassium acetate: 5.7 g
1,4-Dioxane: 170 ml

Next, 0.19 g of [1,1′-bis(diphenylphosphino)ferrocene]palladium(II) dichloride dichloromethane adduct was added, and the mixture was heated and stirred at 100° C. for 7 hours. After the mixture was cooled to room temperature, water and toluene were added, and the organic layer was collected by liquid separation. The organic layer was dehydrated with anhydrous magnesium sulfate and thereafter concentrated under reduced pressure, to obtain a crude product. The crude product was purified by column chromatography (ethyl acetate/n-hexane; ratio of 1:20), to obtain 7.6 g of a white powder of Intermediate 1 (yield: 40%).

### Synthesis of Intermediate 2

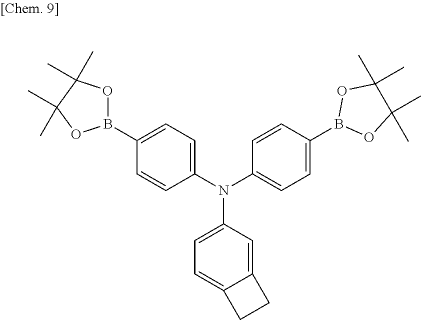

### Intermediate 2

Intermediate 2 is used to introduce a partial structure of thermally cross-linkable structural unit Q (general formula (4e) in FIG. 10) in the repeating unit represented by general formula (3).

The following components were placed in a nitrogen-purged reaction vessel, and aerated with nitrogen gas for 30 minutes.
N,N-bis(4-bromophenyl)-N-(benzocyclobuten-4-yl)-amine: 8.0 g
Bis(pinacolato)diboron: 9.9 g
Potassium acetate: 4.6 g
1,4-Dioxane: 80 ml

Next, 0.3 g of [1,1′-bis(diphenylphosphino)ferrocene]palladium(II) dichloride dichloromethane adduct was added, and the mixture was heated and stirred at 90° C. for 11 hours. After the mixture was cooled to room temperature, water and toluene were added, and the organic layer was collected by liquid separation. The organic layer was dehydrated with anhydrous magnesium sulfate and thereafter concentrated under reduced pressure, to obtain a crude product. The crude product was recrystallized by toluene/methanol (ratio of 1:2), to obtain 3.4 g of a white powder of Intermediate 2 (yield: 35%).

### Synthesis of Intermediate 3

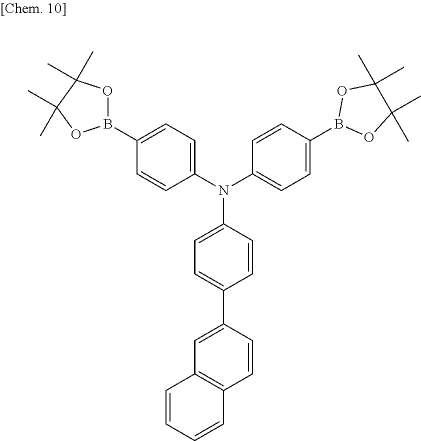

### Intermediate 3

Intermediate 3 is used to introduce a partial structure of Structural unit 2-1 which is a repeating unit shown in FIG. 5.

The following components were placed in a nitrogen-purged reaction vessel, and aerated with nitrogen gas for 30 minutes.
Bis(p-bromophenyl)[p-(2-naphthyl)phenyl]amine: 7.3 g
Bis(pinacolato)diboron: 7.4 g
Potassium acetate: 4.1 g
1,4-Dioxane: 50 ml

Next, 0.11 g of [1,1′-bis(diphenylphosphino)ferrocene]palladium(II) dichloride dichloromethane adduct was added, and the mixture was heated and stirred at 100° C. for 11 hours. After the mixture was cooled to room temperature, methanol was added and stirred for 1 hour, followed by filtration. The obtained solid was dissolved in chloroform, then 40 g of silica gel was added to perform adsorption purification, followed by concentration under reduced pressure, to obtain a crude product. The crude product was recrystallized by chloroform/methanol (ratio of 1:6), to obtain 3.9 g of a white powder of Intermediate 3 (yield: 45%).

### Synthesis of Intermediate 4

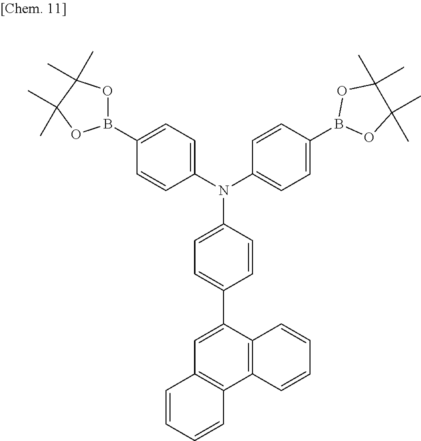

### Intermediate 4

Intermediate 4 is used to introduce a partial structure of Structural unit 2-3 which is a repeating unit shown in FIG. 5.

The following components were placed in a nitrogen-purged reaction vessel, and aerated with nitrogen gas for 30 minutes.
Bis(p-bromophenyl)[p-(9-phenanthrenyl)phenyl]amine: 20.0 g
Bis(pinacolato)diboron: 18.4 g
Potassium acetate: 10.2 g
1,4-Dioxane: 100 ml

Next, 0.28 g of [1,1′-bis(diphenylphosphino)ferrocene]palladium(II) dichloride dichloromethane adduct was added, and the mixture was heated and stirred at 96° C. for 7 hours. The mixture was cooled to room temperature, followed by filtration. The obtained solid was dissolved in chloroform, then 100 g of silica gel was added to perform adsorption purification, followed by concentration under reduced pressure, to obtain a crude product. The crude product was thermally dispersed and washed with toluene, to obtain 12.9 g of a white powder of Intermediate 4 (yield: 55%).

### Synthesis of Intermediate 5

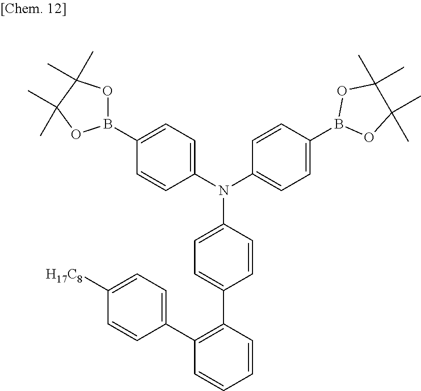

### Intermediate 5

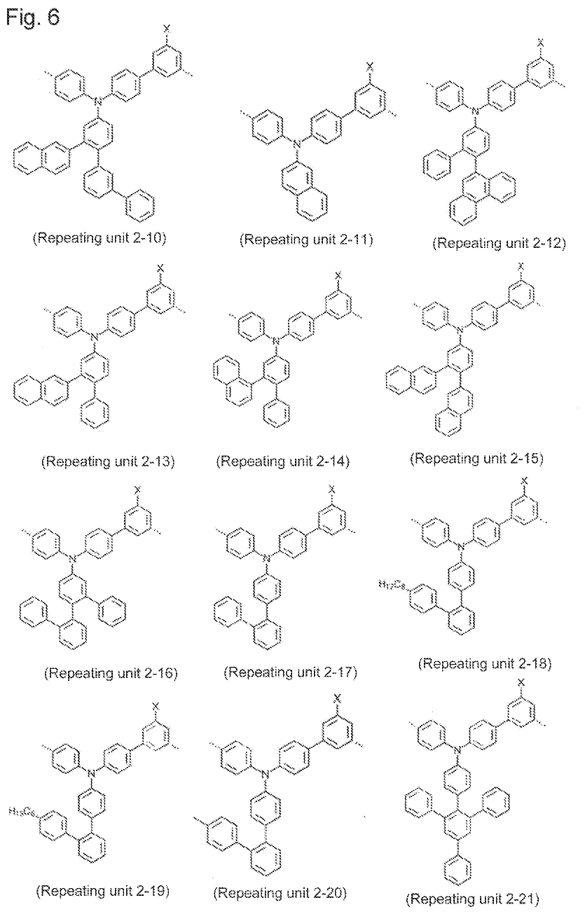

Intermediate 5 is used to introduce a partial structure of Structural unit 2-18 which is a repeating unit shown in FIG. 6.

The following components were placed in a nitrogen-purged reaction vessel, and aerated with nitrogen gas for 30 minutes.
Bis(p-bromophenyl){p-[o-(p-octylphenyl)phenyl]phenyl}amine: 15.8 g
Bis(pinacolato)diboron: 12.6 g
Potassium acetate: 7.0 g
1,4-Dioxane: 100 ml

Next, 0.19 g of [1,1′-bis(diphenylphosphino)ferrocene]palladium(II) dichloride dichloromethane adduct was added, and the mixture was heated and stirred at %° C. for 10 hours. After the mixture was cooled to room temperature, water and toluene were added, and the organic layer was collected by liquid separation. The organic layer was dehydrated with anhydrous magnesium sulfate and thereafter concentrated under reduced pressure, to obtain a crude product. The crude product was purified by column chromatography (toluene/ethyl acetate; ratio of 40:1), to obtain 4.7 g of a white powder of Intermediate 5 (yield: 26%).

### Synthesis of Intermediate 6

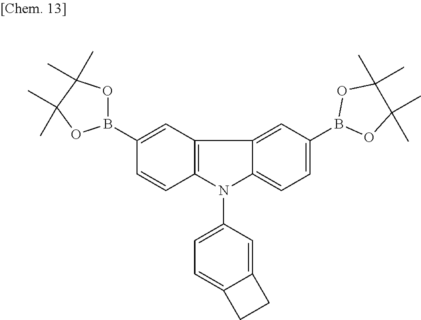

### Intermediate 6

Intermediate 6 is used to introduce a partial structure of thermally cross-linkable structural unit Q (general formula (4g) in FIG. 10) in the repeating unit represented by general formula (3).

The following components were placed in a nitrogen-purged reaction vessel, and aerated with nitrogen gas for 30 minutes.
N-(benzocyclobuten-4-yl)-3,6-dibromocarbazole: 19.6 g
Bis(pinacolato)diboron: 24.5 g
Potassium acetate: 13.5 g
1,4-Dioxane: 120 ml

Next, 0.4 g of [1,1′-bis(diphenylphosphino)ferrocene]palladium(II) dichloride dichloromethane adduct was added, and the mixture was heated and stirred at 97° C. for 5 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was recrystallized by toluene/methanol (ratio of 1:5), to obtain 14.5 g of a white powder of Intermediate 6 (yield: 61%).

### Synthesis of Intermediate 7

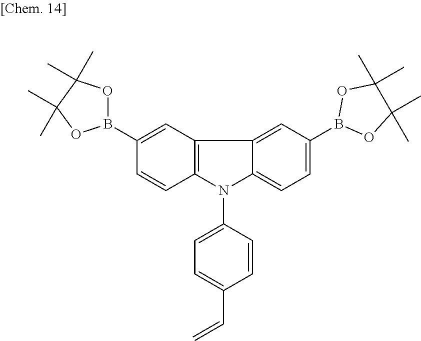

### Intermediate 7

Intermediate 7 is used to introduce a partial structure of thermally cross-linkable structural unit Q (general formula (4a) in FIG. 10) in the repeating unit represented by general formula (3).

The following components were placed in a nitrogen-purged reaction vessel, and were cooled to 0° C.
Methyltriphenylphosphonium bromide: 11.5 g
Tetrahydrofuran: 75 ml

Next, 3.6 g of potassium t-butoxide was added and stirred for 1 hour, and then 11.3 g of 4-(bis(4-(4,4,5,5-tetramethyl-1,3,2-dioxaborolan-2-yl)phenyl)amino)benzaldehyde was dissolved in 75 ml of tetrahydrofuran. The solution was added slowly, and the mixture was stirred for 5 hours while slowly raising the temperature to room temperature. Water and toluene were added, and the organic layer was collected by liquid separation. The organic layer was dehydrated with anhydrous sodium sulfate and thereafter concentrated under reduced pressure, to obtain a crude product. The crude product was purified by column chromatography (toluene/ethyl acetate: ratio of 40:1), to obtain 3.6 g of a pale yellowish-white powder of Intermediate 7 (yield: 32%).

### Synthesis of Intermediate 8

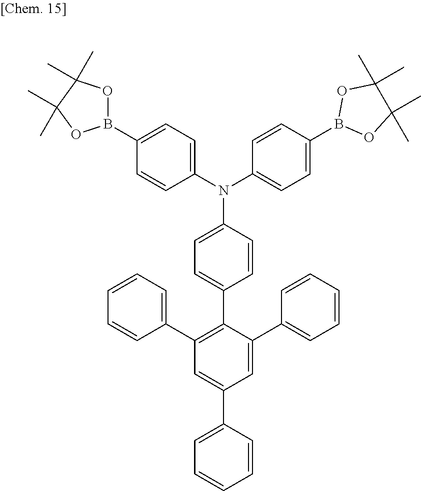

### Intermediate 8

Intermediate 8 is used to introduce a partial structure of Structural unit 2-21 which is a repeating unit shown in FIG. 5.

The following components were placed in a nitrogen-purged reaction vessel, and aerated with nitrogen gas for 30 minutes.
Bis(p-bromophenyl)[p-(2,4,6-triphenylphenyl)phenyl]amine: 23.9 g
Bis(pinacolato)diboron: 18.0 g
Potassium acetate: 9.9 g
1,4-Dioxane: 120 ml

Next, 0.3 g of [1,1′-bis(diphenylphosphino)ferrocene]palladium(II) dichloride dichloromethane adduct was added, and the mixture was heated and stirred at 98° C. for 4 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was recrystallized by toluene, to obtain 13.3 g of a white powder of Intermediate 8 (yield: 49%).

### <Synthesis of Intermediate 9>

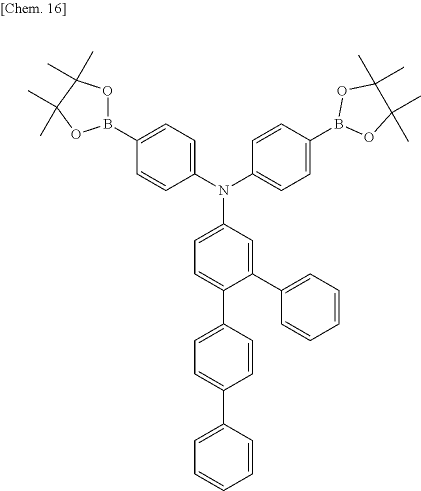

### Intermediate 9

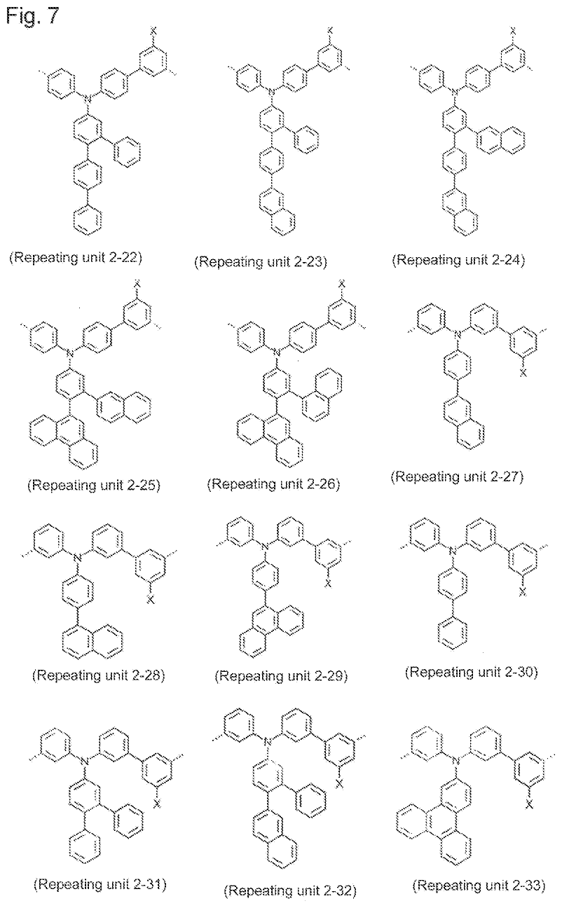

Intermediate 9 is used to introduce a partial structure of Structural unit 2-22 which is a repeating unit shown in FIG. 7.

The following components were placed in a nitrogen-purged reaction vessel, and aerated with nitrogen gas for 30 minutes.
Bis(p-bromophenyl)[3-phenyl-4-(p-phenylphenyl)phenyl]amine: 17.0 g
Bis(pinacolato)diboron: 14.4 g
Potassium acetate: 7.9 g
1,4-Dioxane: 85 ml

Next, 0.2 g of [1,1′-bis(diphenylphosphino)ferrocene]palladium(II) dichloride dichloromethane adduct was added, and the mixture was heated and stirred at 99° C. for 6 hours. After the mixture was cooled to room temperature, water and toluene were added, and the organic layer was collected by liquid separation. The organic layer was dehydrated with anhydrous sodium sulfate and thereafter concentrated under reduced pressure, to obtain a crude product. The crude product was recrystallized by toluene, to obtain 7.0 g of an off-white powder of Intermediate 9 (yield: 36%).

### Synthesis of Intermediate 10

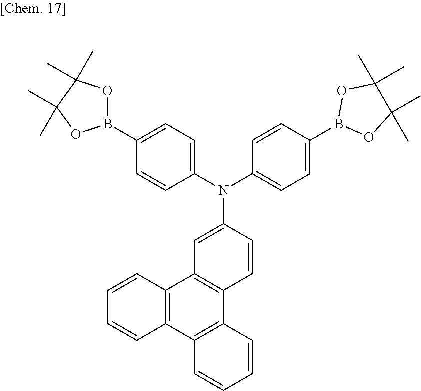

### Intermediate 10

Intermediate 10 is used to introduce a partial structure of Structural unit 2-7 which is a repeating unit shown in FIG. 5.

The following components were placed in a nitrogen-purged reaction vessel, and aerated with nitrogen gas for 30 minutes.
Bis(p-bromophenyl)-2-triphenylenyl amine: 31.7 g
Bis(pinacolato)diboron: 30.6 g
Potassium acetate: 16.9 g
1,4-Dioxane: 160 ml

Next, 0.5 g of [1,1′-bis(diphenylphosphino)ferrocene]palladium(II) dichloride dichloromethane adduct was added, and the mixture was heated and stirred at 100° C. for 10 hours. After the mixture was cooled to room temperature, water and chloroform were added, and the organic layer was collected by liquid separation. The organic layer was dehydrated with anhydrous sodium sulfate and thereafter concentrated under reduced pressure, to obtain a crude product. The crude product was washed with toluene, to obtain 16.0 g of an off-white powder of Intermediate 10 (yield: 43%).

### Example 1

### Synthesis of High Molecular Weight Compound I:

The following components were placed in a nitrogen-purged reaction vessel, and aerated with nitrogen gas for 30 minutes.
Intermediate 1: 3.6 g
Intermediate 3: 1.4 g
Intermediate 2: 0.4 g
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 86° C. for 9.5 hours. Then, 19 mg of phenylboronic acid was added, and the mixture was stirred for 1 hour. Next, 264 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 2.5 g of High molecular weight compound I (yield: 57%).

The average molecular weight measured by GPC and the degree of dispersion of High molecular weight compound I were as follows.
Number-average molecular weight Mn (in terms of polystyrene): 65,000
Weight-average molecular weight Mw (in terms of polystyrene); 170,000
Degree of dispersion (Mw/Mn): 2.6

High molecular weight compound I was also subjected to NMR measurement.

The ¹H-NMR measurement results of FIG. 16 show that the chemical composition formula of High molecular weight compound I was as follows.

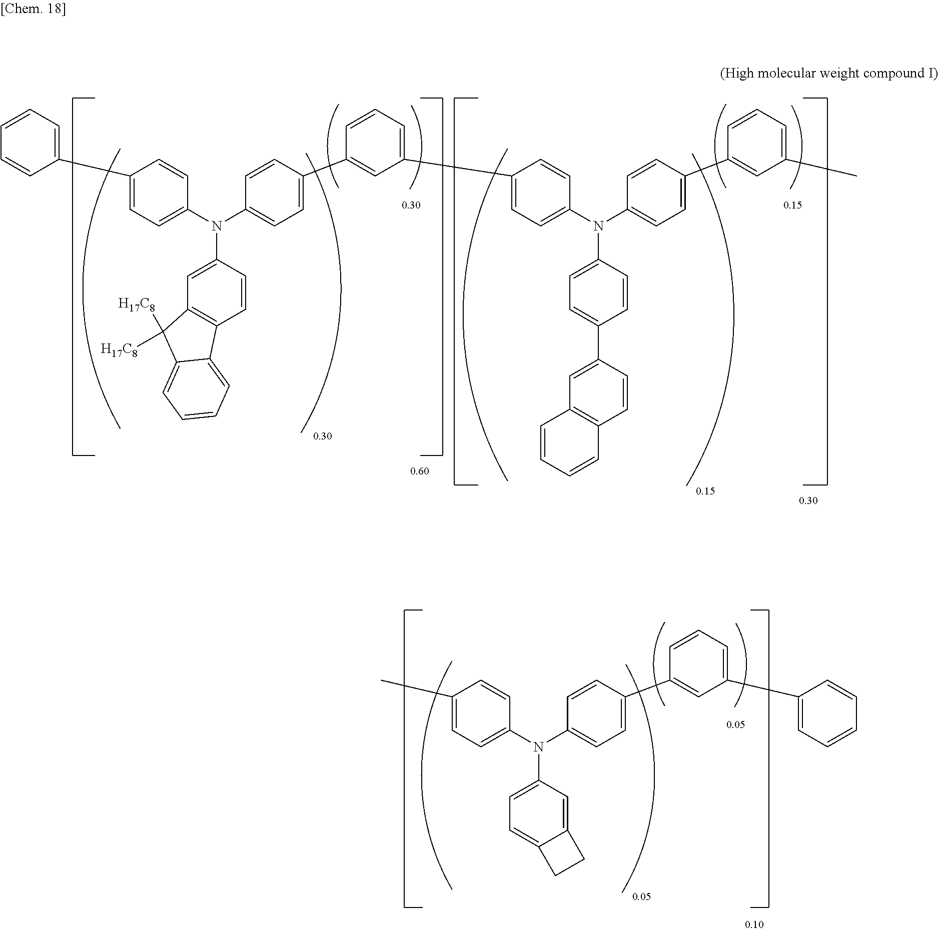

As can be understood from the chemical composition above, High molecular weight compound I contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 2

### Synthesis of High Molecular Weight Compound II

The following components were placed in a nitrogen-purged reaction vessel, and aerated with nitrogen gas for 30 minutes.
Intermediate 1: 4.2 g
Intermediate 4: 1.0 g
Intermediate 2: 0.4 g
1,3-Dibromobenzene: 1.8 g
Tripotassium phosphate: 7.4 g
Toluene: 9 ml
Water: 5 ml
1,4-Dioxane: 27 ml

Next, 1.5 mg of palladium(II) acetate and 12.4 mg of tri-o-tolylphosphine were added, and the mixture was heated and stirred at 86° C. for 8.5 hours. Then, 19 mg of phenylboronic acid was added, and the mixture was stirred for 1 hour. Next, 262 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 2.8 g of High molecular weight compound II (yield: 62%).

The average molecular weight measured by GPC and the degree of dispersion of High molecular weight compound II were as follows.
Number-average molecular weight Mn (in terms of polystyrene); 55,000
Weight-average molecular weight Mw (in terms of polystyrene): 94,000
Degree of dispersion (Mw/Mn): 1.7

High molecular weight compound II was also subjected to NMR measurement.

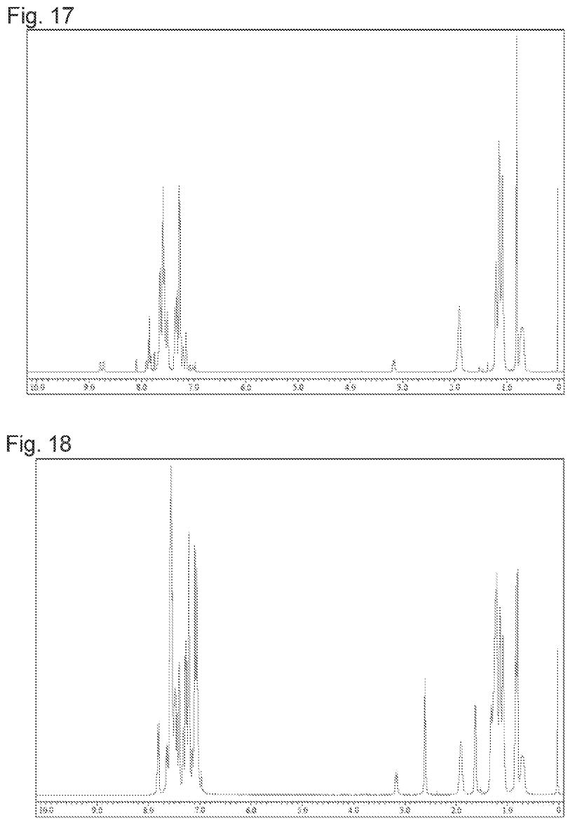

The ¹H-NMR measurement results of FIG. 17 show that the chemical composition formula of High molecular weight compound II was as follows.

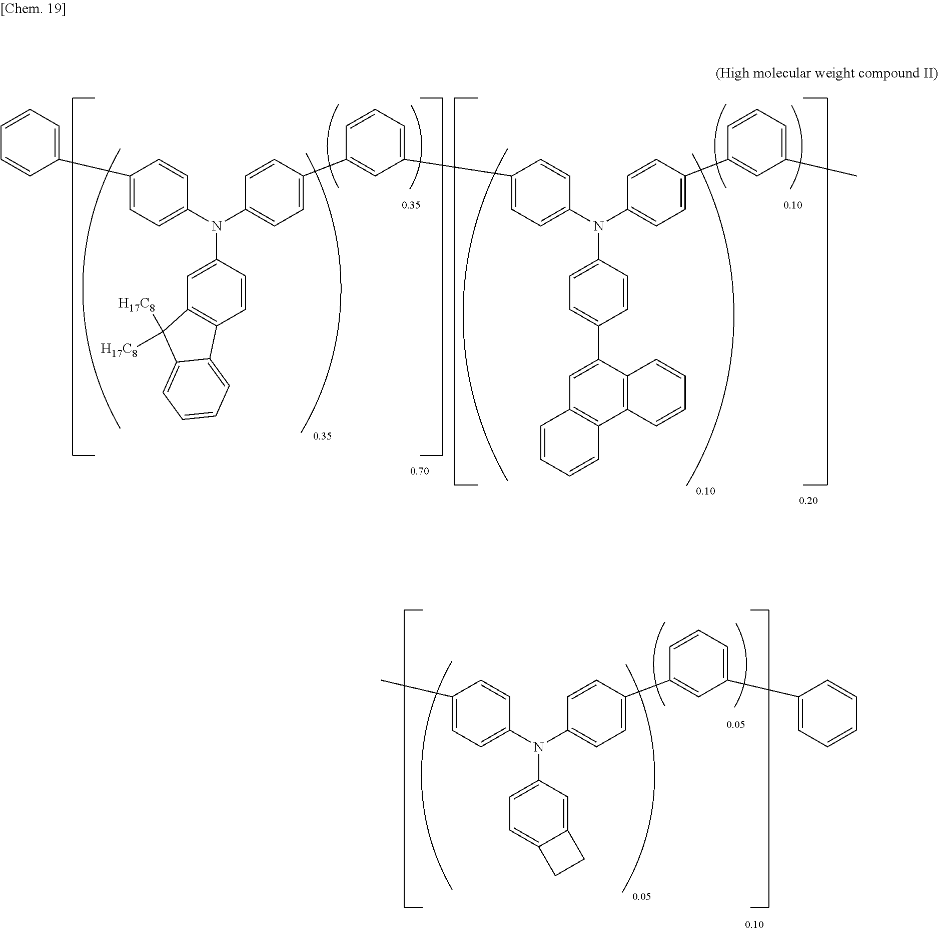

As can be understood from the chemical composition above, High molecular weight compound II contained 70 mol % of repeating unit A represented by general formula (1), 20 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 3

### Synthesis of High Molecular Weight Compound III

The following components were placed in a nitrogen-purged reaction vessel, and aerated with nitrogen gas for 30 minutes.
Intermediate 1.1.8 g
Intermediate 5: 3.4 g
Intermediate 2: 0.4 g
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 90° C. for 9 hours. Then, 19 mg of phenylboronic acid was added, and the mixture was stirred for 1 hour. Next, 263 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 3.3 g of High molecular weight compound Ill (yield: 71%).

The average molecular weight measured by GPC and the degree of dispersion of High molecular weight compound III were as follows.
Number-average molecular weight Mn (in terms of polystyrene); 71,500
Weight-average molecular weight Mw (in terms of polystyrene): 143,000
Degree of dispersion (Mw/Mn): 2.0

High molecular weight compound III was also subjected to NMR measurement.

The ¹H-NMR measurement results of FIG. 18 show that the chemical composition formula of High molecular weight compound III was as follows.

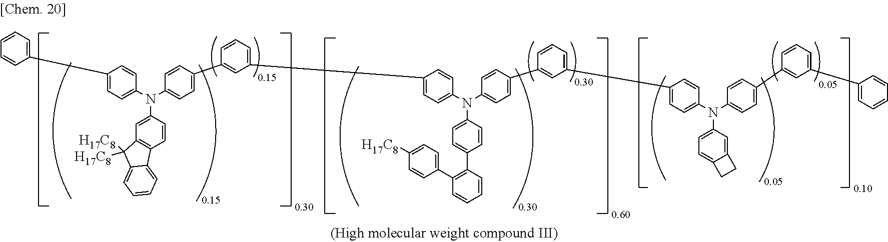

As can be understood from the chemical composition above, High molecular weight compound III contained 30 mol % of repeating unit A represented by general formula (1), 60 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 4

### Synthesis of High Molecular Weight Compound IV

The following components were placed in a nitrogen-purged reaction vessel, and aerated with nitrogen gas for 30 minutes.
Intermediate 1: 3.6 g
Intermediate 8: 1.8 g
Intermediate 2: 0.4 g
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 85° C. for 9 hours. Then, 19 mg of phenylboronic acid was added, and the mixture was stirred for 1 hour. Next, 264 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 3.2 g of High molecular weight compound IV (yield: 72%).

The average molecular weight measured by GPC and the degree of dispersion of High molecular weight compound IV were as follows.
Number-average molecular weight Mn (in terms of polystyrene); 72,000
Weight-average molecular weight Mw (in terms of polystyrene): 122,000
Degree of dispersion (Mw/Mn): 1.7

High molecular weight compound IV was also subjected to NMR measurement.

The ¹H-NMR measurement results of FIG. 19 show that the chemical composition formula of High molecular weight compound IV was as follows.

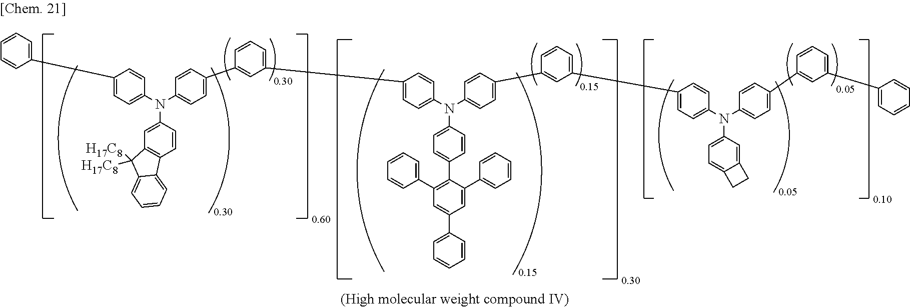

As can be understood from the chemical composition above. High molecular weight compound IV contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 5

### Synthesis of High Molecular Weight Compound V

The following components were placed in a nitrogen-purged reaction vessel, and aerated with nitrogen gas for 30 minutes.
Intermediate 1: 3.8 g
Intermediate 9: 1.7 g
Intermediate 2: 0.4 g
1,3-Dibromobenzene: 1.8 g
Tripotassium phosphate: 7.8 g
Toluene: 9 ml
Water: 5 ml
1,4-Dioxane: 27 ml

Next, 1.6 mg of palladium(II) acetate and 13 mg of tri-o-tolylphosphine were added, and the mixture was heated and stirred at 87° C. for 10 hours. Then, 19 mg of phenylboronic acid was added, and the mixture was stirred for 1 hour. Next, 276 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 3.5 g of High molecular weight compound V (yield: 72%).

The average molecular weight measured by GPC and the degree of dispersion of High molecular weight compound V were as follows.
Number-average molecular weight Mn (in terms of polystyrene): 65,000
Weight-average molecular weight Mw (in terms of polystyrene): 123,000
Degree of dispersion (Mw/Mn): 1.9

High molecular weight compound V was also subjected to NMR measurement.

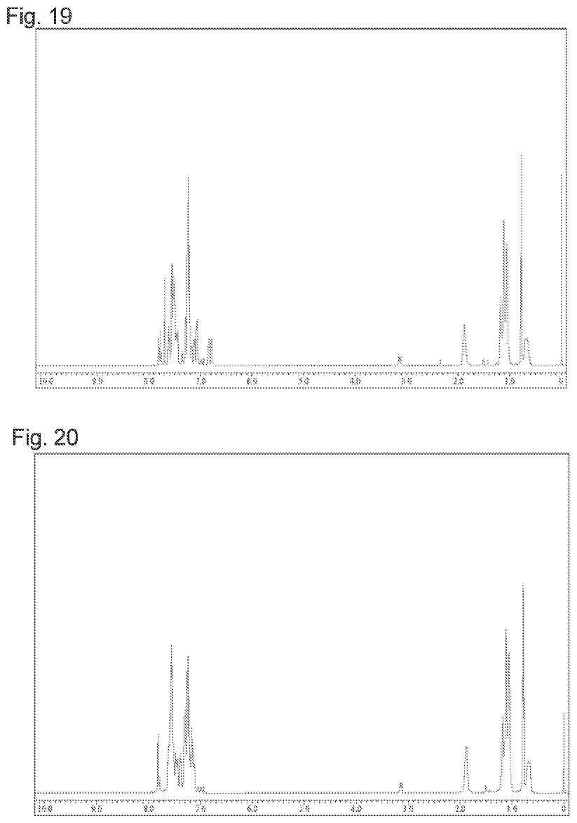

The ¹H-NMR measurement results of FIG. 20 show that the chemical composition formula of High molecular weight compound V was as follows.

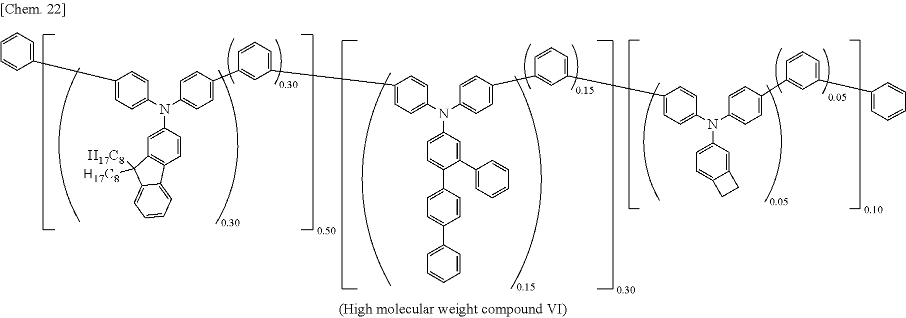

As can be understood from the chemical composition above, High molecular weight compound V contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 6

### Synthesis of High Molecular Weight Compound VI

The following components were placed in a nitrogen-purged reaction vessel, and aerated with nitrogen gas for 30 minutes.
Intermediate 1: 3.7 g
Intermediate 3: 1.4 g
Intermediate 2: 0.4 g
9-(3,5-Dibromophenyl)-9H-carbazole: 3.1 g
Tripotassium phosphate: 6.9 g
Toluene: 9 ml
Water: 5 ml
1,4-Dioxane: 27 ml

Next, 1.4 mg of palladium(II) acetate and 11.5 mg of tri-o-tolylphosphine were added, and the mixture was heated and stirred at 85° C. for 7 hours. Then, 17 mg of phenylboronic acid was added, and the mixture was stirred for 2 hours. Next, 242 mg of bromobenzene was added, and the mixture was stirred for 2 hours. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated four times, followed by drying, to obtain 3.8 g of High molecular weight compound VI (yield: 69%).

The average molecular weight measured by GPC and the degree of dispersion of High molecular weight compound VI were as follows.
Number-average molecular weight Mn (in terms of polystyrene): 135,00)
Weight-average molecular weight Mw (in terms of polystyrene): 257,000
Degree of dispersion (Mw/Mn): 1.9

High molecular weight compound VI was also subjected to NMR measurement.

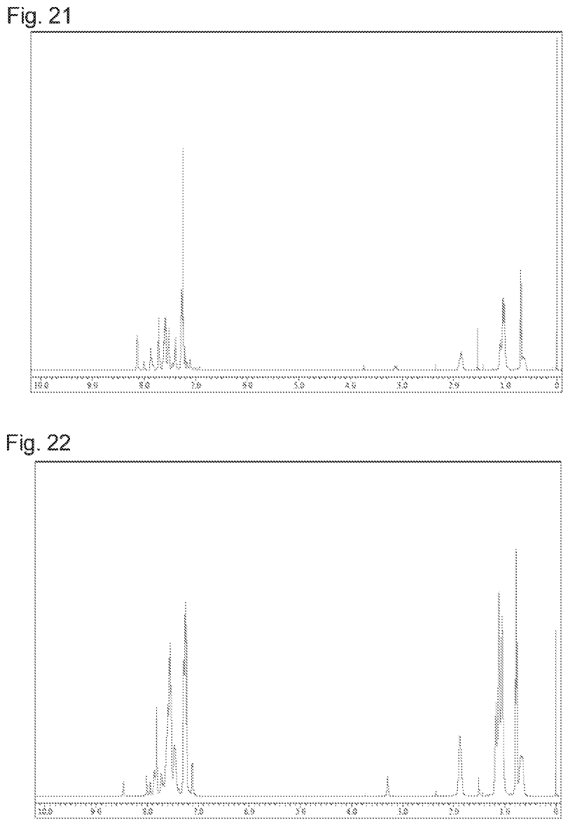

The ¹H-NMR measurement results of FIG. 21 show that the chemical composition formula of High molecular weight compound VI was as follows.

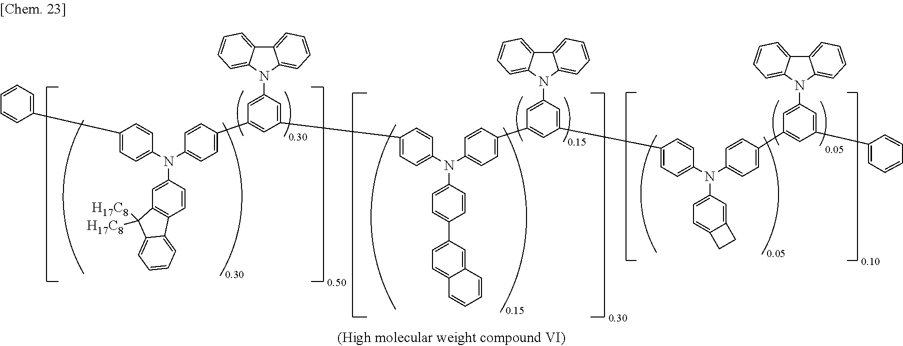

As can be understood from the chemical composition above, High molecular weight compound VI contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 7

### Synthesis of High Molecular Weight Compound VII

The following components were placed in a nitrogen-purged reaction vessel, and aerated with nitrogen gas for 30 minutes.
Intermediate 1: 3.6 g
Intermediate 3: 1.4 g
Intermediate 6: 0.4 g
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 87° C. for 9 hours. Then, 19 mg of phenylboronic acid was added, and the mixture was stirred for 1 hour. Next, 264 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated five times, followed by drying, to obtain 2.2 g of High molecular weight compound VII (yield: 50%).

The average molecular weight measured by GPC and the degree of dispersion of High molecular weight compound VII were as follows.
Number-average molecular weight Mn (in terms of polystyrene): 54,000
Weight-average molecular weight Mw (in terms of polystyrene): 130,000
Degree of dispersion (Mw/Mn): 2.4

High molecular weight compound VII was also subjected to NMR measurement.

The ¹H-NMR measurement results of FIG. 22 show that the chemical composition formula of High molecular weight compound VII was as follows.

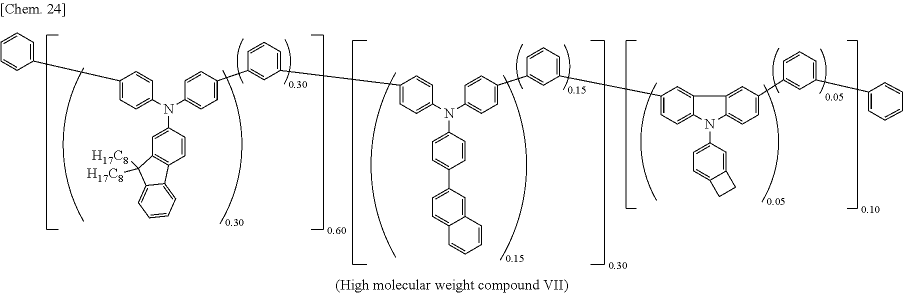

As can be understood from the chemical composition above, High molecular weight compound VII contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 8

### Synthesis of High Molecular Weight Compound VII

The following components were placed in a nitrogen-purged reaction vessel, and aerated with nitrogen gas for 30 minutes.
Intermediate 1: 3.7 g
Intermediate 3: 1.4 g
Intermediate 6: 0.4 g
9-(3,5-Dibromophenyl)-9H-carbazole: 3.1 g
Tripotassium phosphate: 6.9 g
Toluene: 9 ml
Water: 5 ml
1,4-Dioxane: 27 ml

Next, 1.4 mg of palladium(II) acetate and 11.5 mg of tri-o-tolylphosphine were added, and the mixture was heated and stirred at 85° C. for 8 hours. Then, 17 mg of phenylboronic acid was added, and the mixture was stirred for 2 hours. Next, 242 mg of bromobenzene was added, and the mixture was stirred for 2 hours. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated three times, followed by drying, to obtain 3.4 g of High molecular weight compound VIII (yield: 61%).

The average molecular weight measured by GPC and the degree of dispersion of High molecular weight compound VIII were as follows.
Number-average molecular weight Mn (in terms of polystyrene); 123.000
Weight-average molecular weight Mw (in terms of polystyrene): 222,000
Degree of dispersion (Mw/Mn): 1.8

High molecular weight compound VIII was also subjected to NMR measurement.

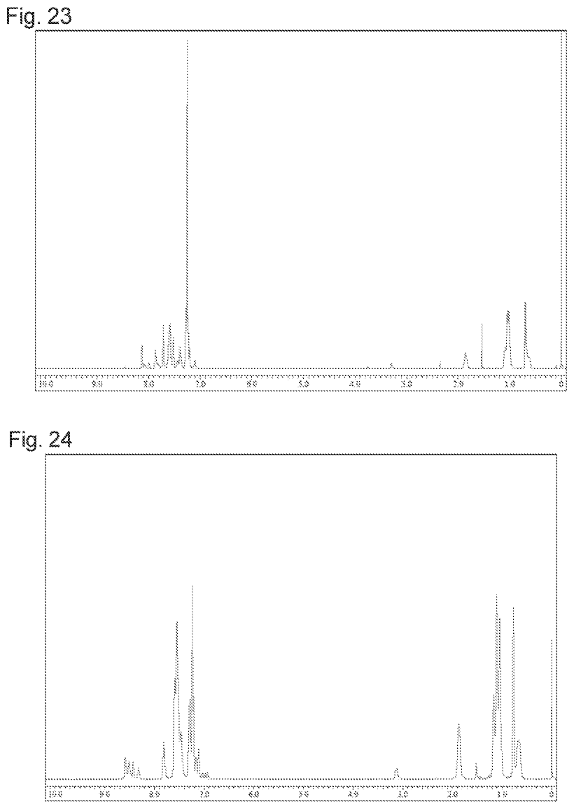

The ¹H-NMR measurement results of FIG. 23 show that the chemical composition formula of High molecular weight compound VIII was as follows.

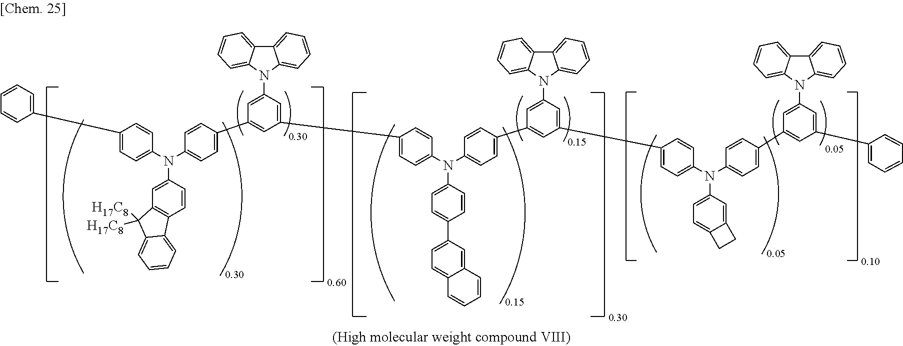

As can be understood from the chemical composition above, High molecular weight compound VIII contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 9

### Synthesis of High Molecular Weight Compound IX

The following components were placed in a nitrogen-purged reaction vessel, and aerated with nitrogen gas for 30 minutes.
Intermediate 1: 3.5 g
Intermediate 10: 1.4 g
Intermediate 2: 0.4 g
1,3-Dibromobenzene: 1.7 g
Tripotassium phosphate: 7.2 g
Toluene: 9 ml
Water: 5 ml
1,4-Dioxane: 27 ml
   Next, 1.5 mg of palladium(II) acetate and 12.0 mg of tri-o-tolylphosphine were added, and the mixture was heated and stirred at 85° C. for 6.5 hours. Then, 18 mg of phenylboronic acid was added, and the mixture was stirred for 1 hour. Next, 255 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 300 ml of n-hexane, and the obtained precipitate was filtered and collected. This operation was repeated six times, followed by drying, to obtain 2.6 g of High molecular weight compound IX (yield: 62%).

The average molecular weight measured by GPC and the degree of dispersion of High molecular weight compound IX were as follows.
Number-average molecular weight Mn (in terms of polystyrene): 55,000
Weight-average molecular weight Mw (in terms of polystyrene): 127,000
Degree of dispersion (Mw/Mn): 2.3

High molecular weight compound IX was also subjected to NMR measurement.

The ¹H-NMR measurement results of FIG. 24 show that the chemical composition formula of High molecular weight compound IX was as follows.

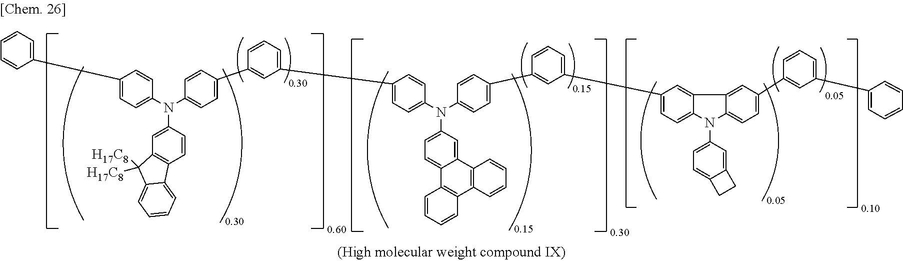

As can be understood from the chemical composition above, High molecular weight compound IX contained 60 mol % of repeating unit A represented by general formula (1), 30 mol % of repeating unit B represented by general formula (2), and 10 mol % of repeating unit C represented by general formula (3) introduced to improve thermal cross-linkability. It should be noted that the molar ratio between the structural units is an estimate value obtained from the ¹H-NMR measurement results.

### Example 10

### Synthesis of High Molecular Weight Compound X

The following components were placed in a nitrogen-purged reaction vessel, and aerated with nitrogen gas for 30 minutes.
Intermediate 1: 3.6 g
Intermediate 3: 1.4 g
Intermediate 2: 0.3 g
Intermediate 7: 78 mg
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 88° C. for 6 hours. Then, 19 mg of phenylboronic acid was added, and the mixture was stirred for 1 hour. Next, 264 mg of bromobenzene was added, and the mixture was stirred for 1 hour. Ten, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 200 ml of n-hexane, and the obtained precipitate was filtered and collected. This operation was repeated four times, followed by drying, to obtain 3.1 g of High molecular weight compound X (yield: 72%).

The average molecular weight measured by GPC and the degree of dispersion of High molecular weight compound X were as follows.
Number-average molecular weight Mn (in terms of polystyrene): 88,000
Weight-average molecular weight Mw (in terms of polystyrene): 352.000
Degree of dispersion (Mw/Mn): 4.0

High molecular weight compound X was also subjected to NMR measurement.

The ¹H-NMR measurement results of FIG. 25 show that the chemical composition formula of High molecular weight compound X was as follows.

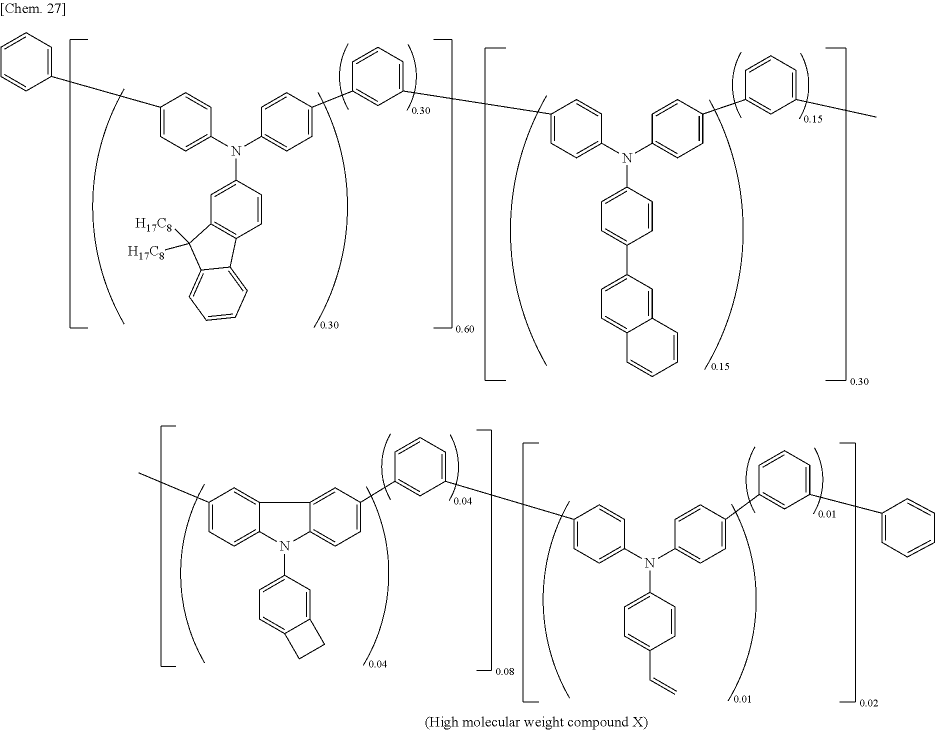

As can be understood from the chemical composition above, High molecular weight compound X contained 60 mol % of repeating unit A represented by general formula (1), 30 mol % of repeating unit B represented by general formula (2), 8 mol % of repeating unit C represented by general formula (3) introduced to improve thermal cross-linkability and including partial structure (4e), and 2 mol % of repeating unit C represented by general formula (3) introduced to improve thermal cross-linkability and including partial structure (4a). It should be noted that the molar ratio between the structural units is an estimate value obtained from the ¹H-NMR measurement results.

### Example 11

### Synthesis of High Molecular Weight Compound XI

The following components were placed in a nitrogen-purged reaction vessel, and aerated with nitrogen gas for 30 minutes.
Intermediate 1: 3.6 g
Intermediate 3: 1.4 g
Intermediate 6: 0.3 g
Intermediate 7: 78 mg
1,3-Dibromobenzene: 1.8 g
Tripotassium phosphate: 7.5 g
Toluene: 9 ml
Water: 5 ml
1,4-Dioxane: 27 ml

Next, 1.5 mg of palladium(II) acetate and 12.5 mg of tri-o-tolylphosphine were added, and the mixture was heated and stirred at 85° C. for 6 hours. Then, 19 mg of phenylboronic acid was added, and the mixture was stirred for 1 hour. Next, 264 mg of bromobenzene was added, and the mixture was stirred for 1 hour. Then, 50 ml of toluene and 50 ml of a 5 wt % aqueous solution of sodium N,N-diethyldithiocarbamate were added and heated, and the mixture was stirred under reflux for 2 hours. After the mixture was cooled to room temperature, the organic layer was collected by liquid separation, and was washed three times with saturated saline solution. The organic layer was dehydrated with anhydrous sodium sulfate and thereafter concentrated under reduced pressure, to obtain a crude polymer. The crude polymer was dissolved in toluene, and silica gel was added to perform adsorption purification, and then the silica gel was removed by filtration. The obtained filtrate was concentrated under reduced pressure, and then the dried solid was dissolved by adding 100 ml of toluene; this was dropped into 200 ml of n-hexane, and the obtained precipitate was filtered and collected. This operation was repeated four times, followed by drying, to obtain 3.1 g of High molecular weight compound XI (yield: 72%).

The average molecular weight measured by GPC and the degree of dispersion of High molecular weight compound XI were as follows.
Number-average molecular weight Mn (in terms of polystyrene): 61,000
Weight-average molecular weight Mw (in terms of polystyrene): 357,000
Degree of dispersion (Mw/Mn): 5.9

High molecular weight compound XI was also subjected to NMR measurement.

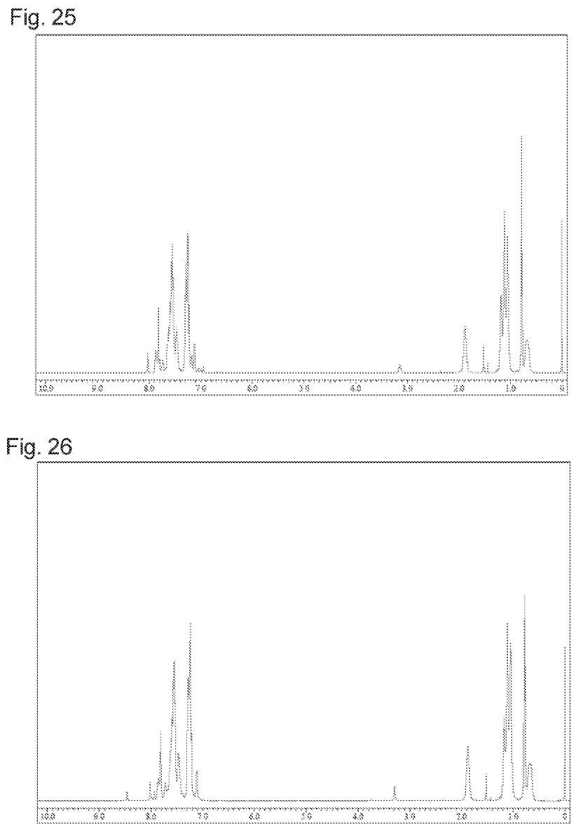

The ¹H-NMR measurement results of FIG. 26 show that the chemical composition formula of High molecular weight compound XI was as follows.

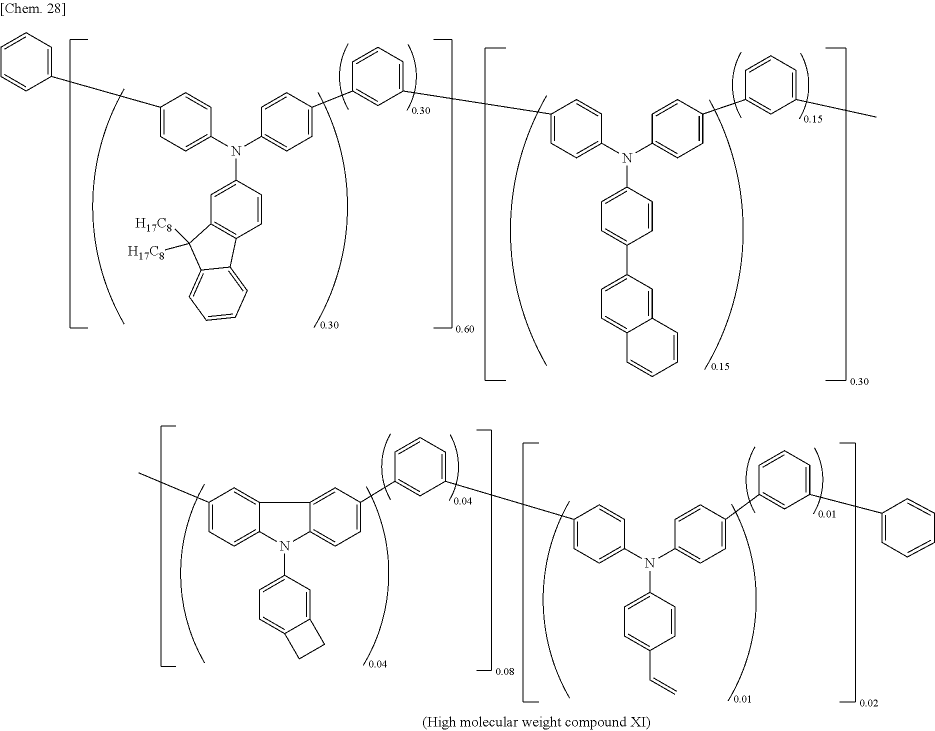

As can be understood from the chemical composition above, High molecular weight compound XI contained 60 mol % of repeating unit A represented by general formula (1), 30 mol % of repeating unit B represented by general formula (2), 8 mol % of repeating unit C represented by general formula (3) introduced to improve thermal cross-linkability and including partial structure (4g), and 2 mol % of repeating unit C represented by general formula (3) introduced to improve thermal cross-linkability and including partial structure (4a). It should be noted that the molar ratio between the structural units is an estimate value obtained from the ¹H-NMR measurement results.

### Example 12

A 80-nm-thick coating film was formed on an ITO substrate by using the respective high molecular weight compounds I to XI synthesized in Examples 1 to 11, and the work function was measured using an ionization potential measurement device (PYS-202 from Sumitomo Heavy Industries. Ltd.). The results are shown below.

TABLE 1

| | Work function |
|---|---|
| High molecular weight compound I (polymer) | 5.67 ev |
| High molecular weight compound II (polymer) | 5.66 ev |
| High molecular weight compound III (polymer) | 5.68 ev |
| High molecular weight compound IV (polymer) | 5.67 ev |
| High molecular weight compound V (polymer) | 5.66 ev |
| High molecular weight compound VI (polymer) | 5.76 ev |
| High molecular weight compound VII (polymer) | 5.67 ev |
| High molecular weight compound VIII (polymer) | 5.75 ev |
| High molecular weight compound IX (polymer) | 5.57 ev |
| High molecular weight compound X (polymer) | 5.61 ev |
| High molecular weight compound XI (polymer) | 5.75 ev |

The results show that the high molecular weight compounds I to XI of the present invention have a suitable energy level and have good hole transportability, compared to the work function of 5.4 eV of typical hole-transporting materials such as NPD, TPD, etc.

### Example 13

### Production and Evaluation of Organic EL Device:

An organic EL device having the layer structure illustrated in FIG. 14 was produced according to the following method.

A glass substrate 1 having a 50-nm-thick ITO film (transparent anode 2) formed thereon was washed with an organic solvent, and then, the surface of the transparent anode 2 was cleaned by UV/ozone treatment. Then, PEDOT/PSS (from Ossila) was spin-coated so as to cover the transparent anode 2 provided on the glass substrate 1, thereby forming a 50-nm-thick film, and this film was dried on a hot plate at 200° C. for 10 minutes, to thereby form a hole injection layer 3.

The high molecular weight compound I obtained in Example 1 was dissolved in toluene to a concentration of 0.6 wt %, to prepare a coating liquid. The substrate provided with the hole injection layer 3 as described above was transferred to a dry nitrogen-purged glove box, and dried on a hot plate at 230° C. for 10 minutes. Then, the coating liquid was spin-coated onto the hole injection layer 3, thereby forming a 25-nm-thick coating layer, followed by drying on a hot plate at 220° C. for 30 minutes, to thereby form a hole transport layer 4.

The substrate provided with the hole transport layer 4 as described above was mounted to a vacuum deposition apparatus, in which the pressure was reduced to 0.001 Pa or lower. Then, a 34-nm-thick light-emitting layer 5 was formed on the hole transport layer 4 by binary vapor deposition by using a blue light-emitting material (EMD-1) and a host material (EMH-1) having the following structural formulas. Note that, in binary vapor deposition, the vapor deposition rate ratio between EMD-1 and EMH-1 was 4:96.

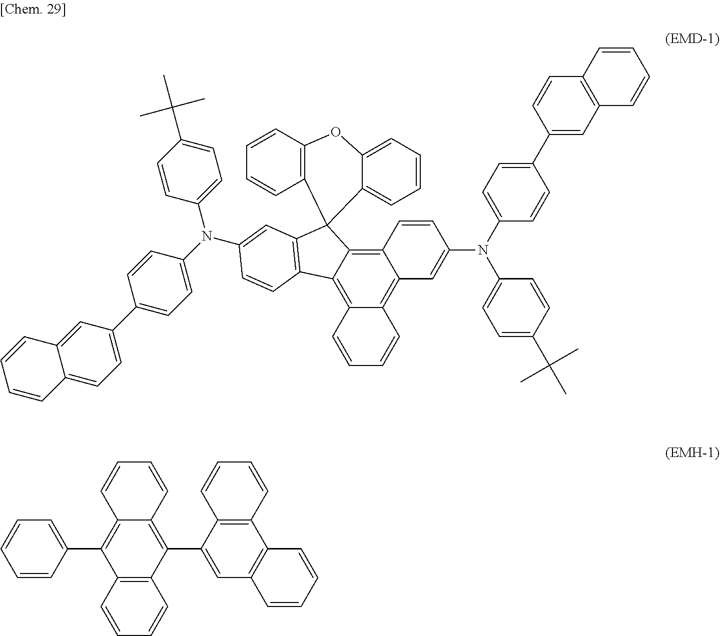

For electron-transporting materials, compounds (ETM-1) and (ETM-2) having the following structural formulas were prepared.

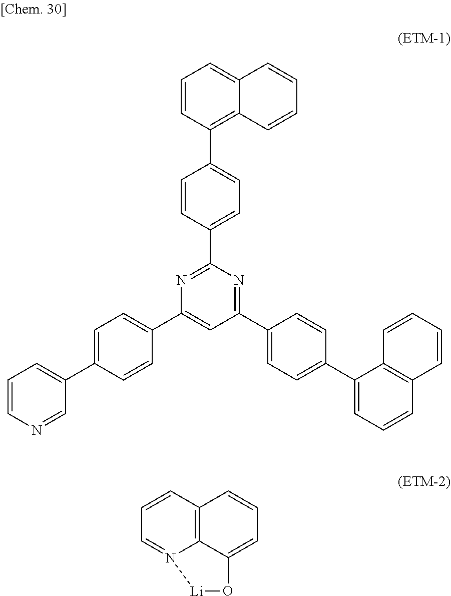

A 20-nm-thick electron transport layer 6 was formed on the aforementioned light-emitting layer 5 by binary vapor deposition by using these electron-transporting materials (ETM-1) and (ETM-2). Note that, in binary vapor deposition, the vapor deposition rate ratio between ETM-1 and ETM-2 was 50:50.

Finally, aluminum was evaporatively deposited to a thickness of 100 nm, to thereby form a cathode 7.

The glass substrate, provided with the transparent anode 2, the hole injection layer 3, the hole transport layer 4, the light-emitting layer 5, the electron transport layer 6, and the cathode 7 as described above, was transferred to a dry nitrogen-purged glove box, and was then bonded with a UV curable resin to another glass substrate for sealing, thereby obtaining an organic EL device. The properties of the produced organic EL device were measured in the atmosphere at atmospheric temperature. Further, the light emission properties of the produced organic EL device when a direct-current voltage was applied thereto were measured. The measurement results are shown in Table 2.

### Example 14

An organic EL device was produced in the same manner as in Example 13, except that a coating liquid prepared by dissolving, in toluene, the compound (high molecular weight compound II) obtained in Example 2 to a concentration of 0.6 wt/o, instead of the high molecular weight compound I, was used to form the hole transport layer 4. For the produced organic EL device, the various properties were evaluated as in Example 13. The results are shown in Table 2.

### Example 15

An organic EL device was produced in the same manner as in Example 13, except that a coating liquid prepared by dissolving, in toluene, the compound (high molecular weight compound III) obtained in Example 3 to a concentration of 0.6 wt %, instead of the high molecular weight compound I, was used to form the hole transport layer 4. For the produced organic EL device, the various properties were evaluated as in Example 13. The results are shown in Table 2.

### Example 16

An organic EL device was produced in the same manner as in Example 13, except that a coating liquid prepared by dissolving, in toluene, the compound (high molecular weight compound IV) obtained in Example 4 to a concentration of 0.6 wt %, instead of the high molecular weight compound I, was used to form the hole transport layer 4. For the produced organic EL device, the various properties were evaluated as in Example 13. The results are shown in Table 2.

### Example 17

An organic EL device was produced in the same manner as in Example 13, except that a coating liquid prepared by dissolving, in toluene, the compound (high molecular weight compound V) obtained in Example 5 to a concentration of 0.6 wt %, instead of the high molecular weight compound I, was used to form the hole transport layer 4. For the produced organic EL device, the various properties were evaluated as in Example 13. The results are shown in Table 2.

### Comparative Example 1

An organic EL device was produced in the same manner as in Example 13, except that a coating liquid prepared by dissolving, in toluene, the following TFB (hole transport polymer) to a concentration of 0.6 wt %, instead of the high molecular weight compound I, was used to form the hole transport layer 4.

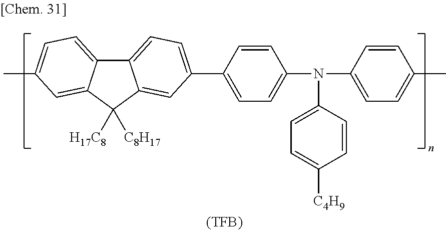

TFB (hole transport polymer) is poly[(9,9-dioctylfluorenyl-2,7-diyl)-co-(4,4′-(N-(4-sec-butylphenyl))diphenylamine](from American Dye Source; Hole Transport Polymer ADS259BE). For the organic EL device of Comparative Example 1, the various properties were evaluated as in Example 13. The results are shown in Table 2.

In the evaluations of the various properties, the voltage, luminance, luminous efficiency, and power efficiency are values when passing a current with a current density of 10 mA/cm². The device life was found by performing constant current driving, with the light emission luminance at the start of light emission (i.e., initial luminance) set to 700 cd/m², and measuring the time it took for the light emission luminance to attenuate to 560 cd/m² (amounting to 80% when the initial luminance is considered as 100%; i.e., 80% attenuation).

TABLE 2

| | | | | Luminous | Power | Device | |
|---|---|---|---|---|---|---|---|
| | Hole | Voltage | Luminance | efficiency | efficiency | life, 80% | |
| | transport layer | [V] | [cd/m²] | [cd/A] | [lm/W] | attenuation | |
| Example 13 | High molecular | 4.12 | 903 | 9.03 | 6.89 | 123 | hours |
| | weight compound I | | | | | | |
| Example 14 | High molecular | 4.23 | 943 | 9.43 | 7.01 | 97 | hours |
| | weight compound II | | | | | | |
| Example 15 | High molecular | 4.53 | 992 | 9.92 | 6.88 | 9 | hours |
| | weight compound III | | | | | | |
| Example 16 | High molecular | 4.40 | 1009 | 10.10 | 7.20 | 14 | hours |
| | weight compound IV | | | | | | |
| Example 17 | High molecular | 4.23 | 942 | 9.42 | 7.00 | 26 | hours |
| | weight compound V | | | | | | |
| Comparative | TFB | 3.89 | 552 | 5.53 | 4.47 | 7 | hours |

Example 1

As shown in Table 2, while the luminous efficiency, when a current having a current density of 10 mA/cm² was passed, was 5.53 cd/A for the organic EL device of Comparative Example 1, the luminous efficiency was 9.03 cd/A for the organic EL device of Example 14, 9.43 cd/A for the organic EL device of Example 15, 9.92 cd/A for the organic EL device of Example 16, 10.10 cd/A for the organic EL device of Example 17, and 9.42 cd/A for the organic EL device of Example 18, all resulting in high efficiency. Further, while the device life (80% attenuation) was 7 hours for the organic EL device of Comparative Example 1, the device life was 123 hours for the organic EL device of Example 14, 97 hours for the organic EL device of Example 15, 9 hours for the organic EL device of Example 16, 14 hours for the organic EL device of Example 17, 26 hours for the organic EL device of Example 18, all resulting in long lifetime.

### Example 18

An organic EL device having the layer structure illustrated in FIG. 15 was produced according to the following method.

A glass substrate 8 having a 50-nm-thick ITO film (transparent anode 9) formed thereon was washed with an organic solvent, and then, the surface of the transparent anode 9 was cleaned by UV/ozone treatment. Then, PEDOT/PSS (from Ossila) was spin-coated so as to cover the transparent anode 9 provided on the glass substrate 8, thereby forming a 50-nm-thick film, and this film was dried on a hot plate at 200° C. for 10 minutes, to thereby form a hole injection layer 10.

A high molecular weight compound (HTM-1) having the following structural formula was dissolved in toluene to a concentration of 0.4 wt %, to prepare a coating liquid. The substrate provided with the hole injection layer 10 as described above was transferred to a dry nitrogen-purged glove box, and dried on a hot plate at 230° C. for 10 minutes. Then, the coating liquid was spin-coated onto the hole injection layer 10, thereby forming a 15-nm-thick coating layer, followed by drying on a hot plate at 220° C. for 30 minutes, to thereby form a hole transport layer 11.

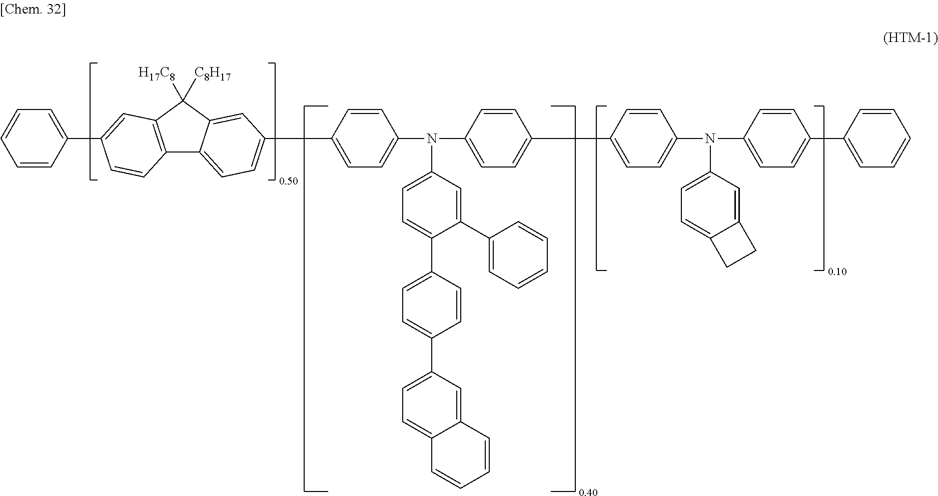

The high molecular weight compound I obtained in Example 1 was dissolved in toluene to a concentration of 0.4 wt %, to prepare a coating liquid. The coating liquid was spin-coated onto the aforementioned hole transport layer 11, thereby forming a 15-nm-thick coating layer, followed by drying on a hot plate at 220° C. for 30 minutes, to thereby form an electron blocking layer 12.

The substrate provided with the electron blocking layer 12 as described above was mounted to a vacuum deposition apparatus, in which the pressure was reduced to 0.001 Pa or lower. Then, a 34-nm-thick light-emitting layer 13 was formed on the electron blocking layer 12 by binary vapor deposition by using the blue light-emitting material (EMD-1) and the host material (EMH-1). Note that, in binary vapor deposition, the vapor deposition rate ratio between EMD-1 and EMH-1 was 4:96.

A 20-nm-thick electron transport layer 14 was formed on the aforementioned light-emitting layer 13 by binary vapor deposition by using the electron-transporting materials (ETM-1) and (ETM-2). Note that, in binary vapor deposition, the vapor deposition rate ratio between ETM-1 and ETM-2 was 50:50.

Finally, aluminum was evaporatively deposited to a thickness of 100 mu, to thereby form a cathode 15.

The glass substrate, provided with the transparent anode 9, the hole injection layer 10, the hole transport layer 11, the electron blocking layer 12, the light-emitting layer 13, the electron transport layer 14, and the cathode 15 as described above, was transferred to a dry nitrogen-purged glove box, and was then bonded with a UV curable resin to another glass substrate for sealing, thereby obtaining an organic EL device. The properties of the produced organic EL device were measured in the atmosphere at atmospheric temperature. Further, the light emission properties of the produced organic EL device when a direct-current voltage was applied thereto were measured. The measurement results are shown in Table 3.

### Example 19

An organic EL device was produced in the same manner as in Example 18, except that the electron blocking laver 12 was formed by spin-coating the coating liquid containing the high molecular weight compound I onto the hole transport layer 11 to thereby form a 15-nm-thick coating laver, and then heating the same on a hot plate at 210° C. for 30 minutes. The various properties of the produced organic EL device were evaluated in the same manner as in Example 18. The results are shown in Table 3.

### Example 20

An organic EL device was produced in the same manner as in Example 18, except that the electron blocking layer 12 was formed by spin-coating the coating liquid containing the high molecular weight compound I onto the hole transport layer 11 to thereby form a 15-nm-thick coating layer, and then heating the same on a hot plate at 220° C. for 20 minutes. The various properties of the produced organic EL device were evaluated in the same manner as in Example 18. The results are shown in Table 3.

### Example 21

An organic EL device was produced in the same manner as in Example 18, except that a coating liquid prepared by dissolving, in toluene, the compound (high molecular weight compound II) obtained in Example 2 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 22

An organic EL device was produced in the same manner as in Example 18, except that a coating liquid prepared by dissolving, in toluene, the compound (high molecular weight compound III) obtained in Example 3 to a concentration of 0.4 w %, instead of the high molecular weight compound I, was used to form the electron blocking layer 12. The various properties of the produced organic EL device were evaluated in the same manner as in Example 18. The results are shown in Table 3.

### Example 23

An organic EL device was produced in the same manner as in Example 18, except that a coating liquid prepared by dissolving, in toluene, the compound (high molecular weight compound IV) obtained in Example 4 to a concentration of 0.4 wt %, instead of the high molecular weight compound I, was used to form the electron blocking laver 12. The various properties of the produced organic EL device were evaluated in the same manner as in Example 18. The results are shown in Table 3.

### Example 24

An organic EL device was produced in the same manner as in Example 18, except that a coating liquid prepared by dissolving, in toluene, the compound (high molecular weight compound V) obtained in Example 5 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 25

An organic EL device was produced in the same manner as in Example 18, except that a coating liquid prepared by dissolving, in toluene, the compound (high molecular weight compound VI) obtained in Example 6 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 26

An organic EL device was produced in the same manner as in Example 18, except that a coating liquid prepared by dissolving, in toluene, the compound (high molecular weight compound VII) obtained in Example 7 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 27

An organic EL device was produced in the same manner as in Example 18, except that a coating liquid prepared by dissolving, in toluene, the compound (high molecular weight compound VIII) obtained in Example 8 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 28

An organic EL device was produced in the same manner as in Example 18, except that a coating liquid prepared by dissolving, in toluene, the compound (high molecular weight compound IX) obtained in Example 9 to a concentration of 0.4 wt %, instead of the high molecular weight compound I, was used to form the electron blocking layer 12. The various properties of the produced organic EL device were evaluated in the same manner as in Example 18. The results are shown in Table 3.

### Example 29

An organic EL device was produced in the same manner as in Example 18, except that a coating liquid prepared by dissolving, in toluene, the compound (high molecular weight compound X) obtained in Example 10 to a concentration of 0.4 wt/o, instead of the high molecular weight compound I, was used to form the electron blocking layer 12. The various properties of the produced organic EL device were evaluated in the same manner as in Example 18. The results are shown in Table 3.

### Example 30

An organic EL device was produced in the same manner as in Example 18, except that a coating liquid prepared by dissolving, in toluene, the compound (high molecular weight compound XI) obtained in Example 11 to a concentration of 0.4 wt %, instead of the high molecular weight compound I, was used to form the electron blocking layer 12. The various properties of the produced organic EL device were evaluated in the same manner as in Example 18. The results are shown in Table 3.

### Comparative Example 2

An organic EL device was produced in the same manner as in Example 18, except that a coating liquid prepared by dissolving, in toluene, TFB (hole transport polymer) to a concentration of 0.4 wt %, instead of the high molecular weight compound I, was used to form the electron blocking layer 12. The various properties of the organic EL device of Comparative Example 2 were evaluated in the same manner as in Example 18. The results are shown in Table 3.

In the evaluations of the various properties, the voltage, luminance, luminous efficiency, and power efficiency are values when passing a current with a current density of 10 mA/cm². The device life was found by performing constant current driving, with the light emission luminance at the start of light emission (i.e., initial luminance) set to 700 cd/m², and measuring the time it took for the light emission luminance to attenuate to 560 cd/m² (amounting to 80% when the initial luminance is considered as 100%: i.e., 80% attenuation).

TABLE 3

| | | Electron blocking | | | Luminous | Power | Device |
|---|---|---|---|---|---|---|---|
| | Electron blocking | layer heating | Voltage | Luminance | efficiency | efficiency | life, 80% |
| | layer | condition | [V] | [cd/m²] | [cd/A] | [lm/W] | attenuation |
| Example 18 | High molecular | 220° C. | 4.02 | 809 | 8.09 | 6.33 | 204 hours |
| | weight compound I | 30 minutes | | | | | |
| Example 19 | High molecular | 210° C. | 3.99 | 794 | 7.93 | 6.25 | 338 hours |
| | weight compound I | 30 minutes | | | | | |
| Example 20 | High molecular | 220° C. | 4.02 | 842 | 8.42 | 6.58 | 306 hours |
| | weight compound I | 20 minutes | | | | | |
| Example 21 | High molecular | 220° C. | 4.05 | 914 | 9.14 | 7.09 | 265 hours |
| | weight compound II | 30 minutes | | | | | |
| Example 22 | High molecular | 220° C. | 4.10 | 897 | 8.97 | 6.87 | 214 hours |
| | weight compound III | 30 minutes | | | | | |
| Example 23 | High molecular | 220° C. | 3.99 | 795 | 7.95 | 6.27 | 258 hours |
| | weight compound IV | 30 minutes | | | | | |
| Example 24 | High molecular | 220° C. | 3.97 | 846 | 8.46 | 6.69 | 242 hours |
| | weight compound V | 30 minutes | | | | | |
| Example 25 | High molecular | 220° C. | 3.96 | 763 | 7.62 | 6.04 | 52 hours |
| | weight compound VI | 30 minutes | | | | | |
| Example 26 | High molecular | 220° C. | 3.89 | 747 | 7.47 | 6.04 | 229 hours |
| | weight compound VI | 30 minutes | | | | | |
| Example 27 | High molecular | 220° C. | 3.96 | 815 | 8.15 | 6.46 | 105 hours |
| | weight compound VIII | 30 minutes | | | | | |
| Example 28 | High molecular | 220° C. | 4.02 | 712 | 7.12 | 5.57 | 122 hours |
| | weight compound IX | 30 minutes | | | | | |
| Example 29 | High molecular | 220° C. | 4.10 | 752 | 7.52 | 5.77 | 218 hours |
| | weight compound X | 30 minutes | | | | | |
| Example 30 | High molecular | 220° C. | 4.06 | 686 | 6.86 | 5.31 | 295 hours |
| | weight compound XI | 30 minutes | | | | | |
| Comparative | TFB | 220° C. | 4.02 | 550 | 5.50 | 4.29 | 11 hours |
| Example 2 | | 30 minutes | | | | | |

As shown in Table 3, while the luminous efficiency, when a current having a current density of 10 mA/cm² was passed, was 5.50 cd/A for the organic EL device of Comparative Example 2, the luminous efficiency was 8.09 cd/A for the organic EL device of Example 18, 7.93 cd/A for the organic EL device of Example 19, and 8.42 cd/A for the organic EL device of Example 20, all resulting in high efficiency. Further, while the device life (80% attenuation) was 11 hours for the organic EL device of Comparative Example 2, the device life was 204 hours for the organic EL device of Example 18, 338 hours for the organic EL device of Example 19, and 306 hours for the organic EL device of Example 20, all resulting in long lifetime. Also, the lifetime tended to become even longer in conditions where the heating temperature was lower or the heating time was shorter.

Further, as shown in Table 3, while the luminous efficiency, when a current having a current density of 10 mA/cm² was passed, was 5.50 cd/A for the organic EL device of Comparative Example 2, the luminous efficiency was 9.14 cd/A for the organic EL device of Example 21, 8.97 cd/A for the organic EL device of Example 22, 7.95 cd/A for the organic EL device of Example 23, 8.46 cd/A for the organic EL device of Example 24, 7.62 cd/A for the organic EL device of Example 25, 7.47 cd/A for the organic EL device of Example 26, 8.15 cd/A for the organic EL device of Example 27, 7.12 cd/A for the organic EL device of Example 28, 7.52 cd/A for the organic EL device of Example 29, and 6.86 cd/A for the organic EL device of Example 30, all resulting in high efficiency.

Further, as shown in Table 3, while the device life (80% attenuation) was 11 hours for the organic EL device of Comparative Example 2, the device life was 265 hours for the organic EL device of Example 21, 214 hours for the organic EL device of Example 22, 258 hours for the organic EL device of Example 23, 242 hours for the organic EL device of Example 24, 52 hours for the organic EL device of Example 25, 229 hours for the organic EL device of Example 26, 105 hours for the organic EL device of Example 27, 122 hours for the organic EL device of Example 28, 218 hours for the organic EL device of Example 29, 295 hours for the organic EL device of Example 30, all resulting in long lifetime.

### Industrial Applicability

The high molecular weight compound of the present invention has high hole transportability and excellent electron blockability, and is thus an excellent compound for coating-type organic EL devices. By producing a coating-type organic EL device using this compound, it is possible to achieve high luminous efficiency and power efficiency, and also improve durability. For example, application can be expanded to various uses, such as home electrical appliances and lightings.

### REFERENCE SIGNS LIST

1, 8: Glass substrate
2, 9: Transparent anode
3, 10: Hole injection layer
4, 11: Hole transport layer
5, 13: Light-emitting layer
6, 14: Electron transport layer
7, 15: Cathode
12: Electron blocking laver

1. A high molecular weight compound comprising a repeating unit represented by general formula (1) below and a repeating unit represented by general formula (2) below, and having a weight-average molecular weight of 10,000 or greater to less than 1,000,000 in terms of polystyrene: 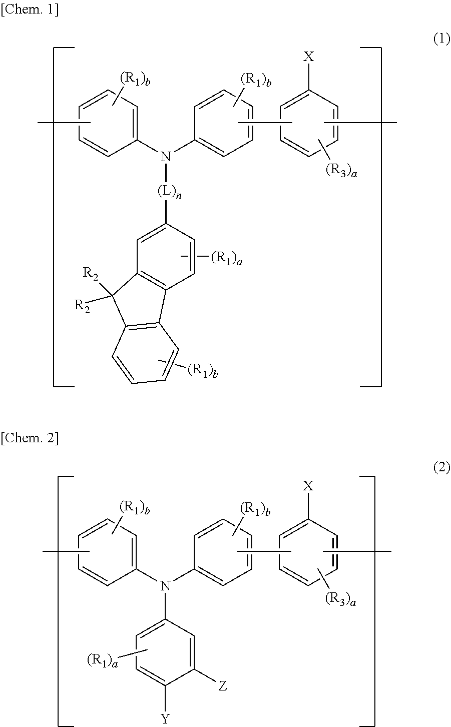
wherein, in the formulas:
R₁ and R₃ may be the same or different from one another, and each represent a deuterium atom, a cyano group, a nitro group, a halogen atom, an alkyl group having 40 or fewer carbon atoms, a cycloalkyl group having 40 or fewer carbon atoms, an alkyloxy group having 40 or fewer carbon atoms, a cycloalkyloxy group having 40 or fewer carbon atoms, an alkenyl group having 40 or fewer carbon atoms, or an aryloxy group having 40 or fewer carbon atoms;
R₁ in general formula (1) and R₁ in general formula (2) may be the same or different from one another, and R₃ in general formula (1) and R₃ in general formula (2) represent the same group;
a represents an integer from 0 to 3, and b represents an integer from 0 to 4;
R₂ represents an alkyl group having 3 to 40 carbon atoms, a cycloalkyl group having 3 to 40 carbon atoms, or an alkyloxy group having 3 to 40 carbon atoms;
L represents a phenylene group, and n represents an integer from 0 to 3;
X represents a hydrogen atom, an amino group optionally having a substituent, a monovalent aryl group optionally having a substituent, or a monovalent heteroaryl group optionally having a substituent, wherein the substituents may be bonded to each other via a single bond, a methylene group optionally having a substituent, an oxygen atom, or a sulfur atom, to form a ring;
X in general formula (1) and X in general formula (2) represent the same group; and
Y represent a monovalent aryl group optionally having a substituent, and Z represent a hydrogen atom, a monovalent aryl group optionally having a substituent, or a monovalent heteroaryl group optionally having a substituent, wherein Y and Z may be bonded to each other via a single bond, a methylene group optionally having a substituent, an oxygen atom, or a sulfur atom, to form a ring.

2. The high molecular weight compound according to claim 1, wherein, in the general formulas (1) and (2), a and b are 0.

3. The high molecular weight compound according to claim 1, wherein, in the general formula (1), R₂ is an alkyl group having 3 to 40 carbon atoms.

4. The high molecular weight compound according to claim 1, wherein, in the general formulas (1) and (2), X is a hydrogen atom, a diphenylamino group, a phenyl group, a naphthyl group, a dibenzofuranyl group, a dibenzothienyl group, a phenanthrenyl group, a fluorenyl group, a carbazolyl group, an indenocarbazolyl group, or an acridinyl group.

5. The high molecular weight compound according to claim 1, comprising a repeating unit represented by general formula (3) below and including a thermally cross-linkable structural unit Q: 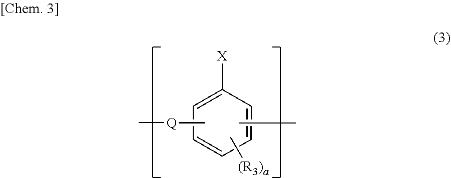
wherein, in the formula, R₃, X, and a are all the same as those described in general formula (1).

6. The high molecular weight compound according to claim 5, wherein the thermally cross-linkable structural unit Q is a structural unit represented by general formulas (4a) to (4z) below: 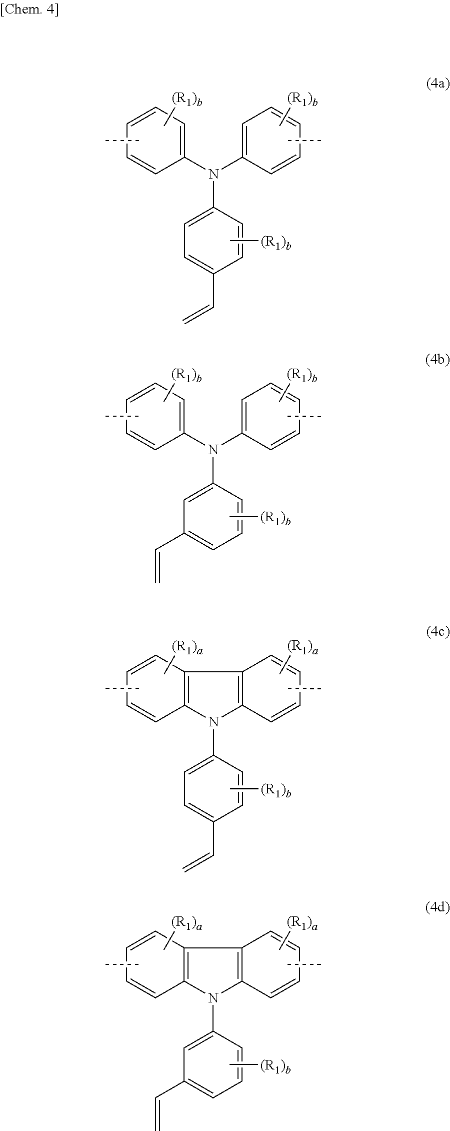 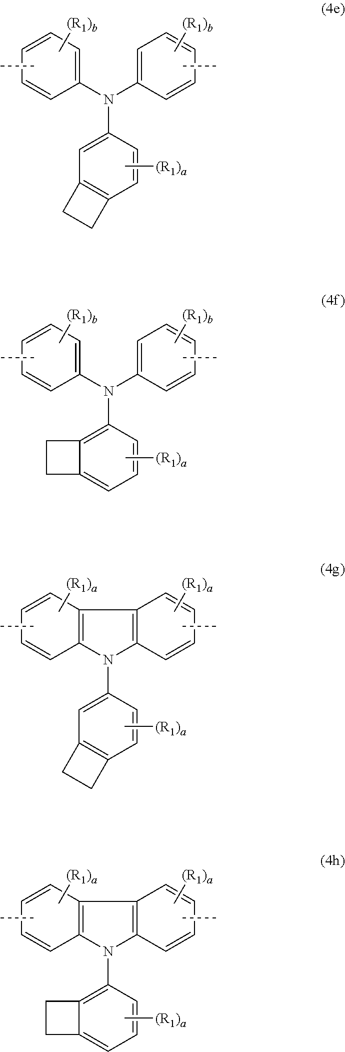 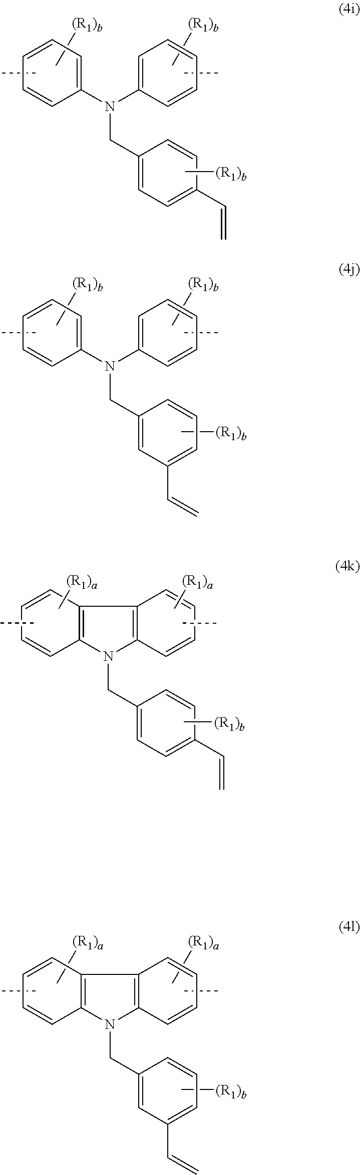 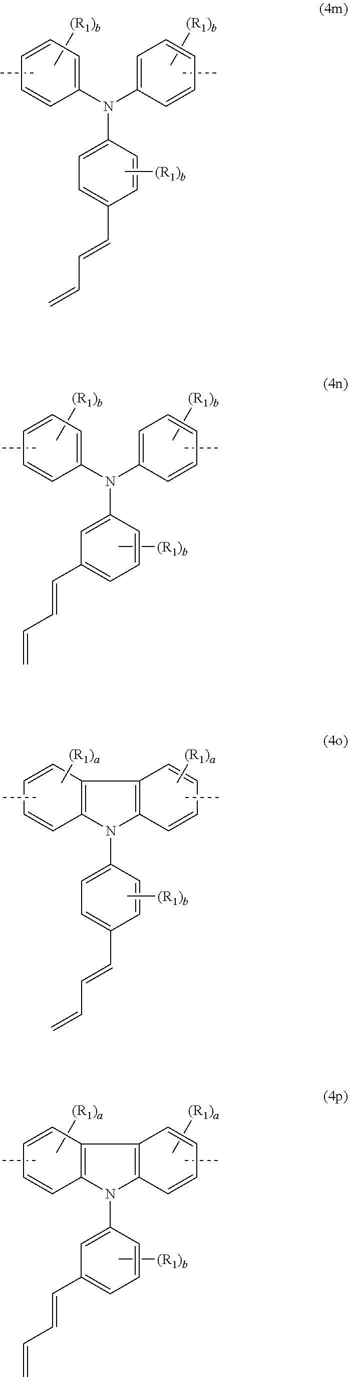 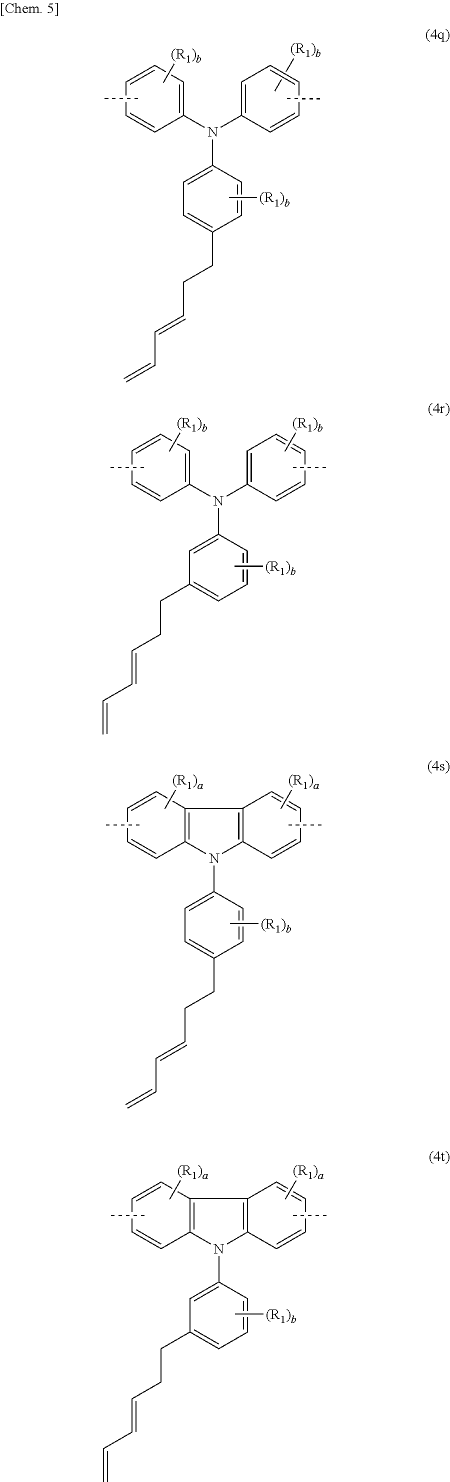 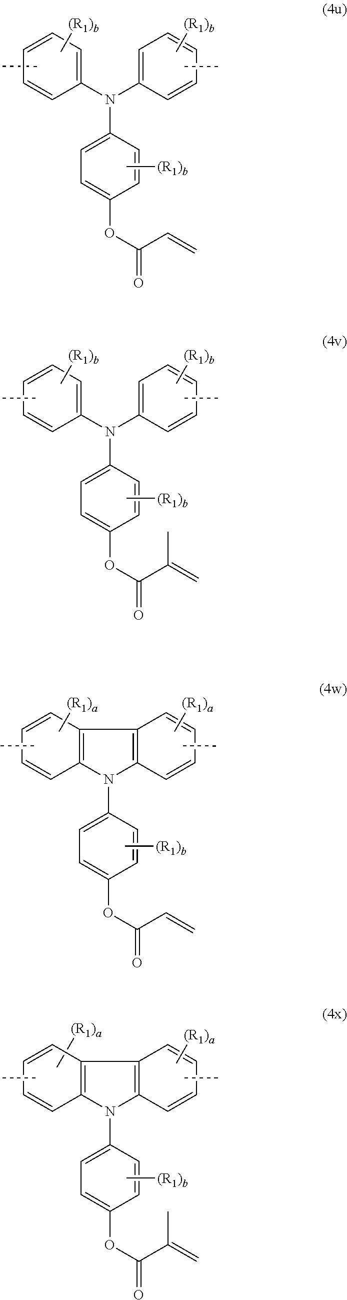 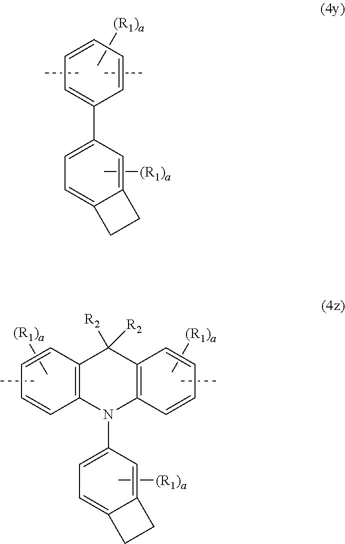
wherein, in the formulas, R₁, R₂, a, and b are all the same as those described in general formula (1).

7. An organic electroluminescent device comprising a pair of electrodes, and an organic layer interposed between the electrodes, wherein
the organic layer comprises, as a constituent material, the high molecular weight compound according to claim 1.

8. The organic electroluminescent device according to claim 7, wherein the organic layer is a hole transport layer.

9. The organic electroluminescent device according to claim 7, wherein the organic layer is an electron blocking layer.

10. The organic electroluminescent device according to claim 7, wherein the organic layer is a hole injection layer.

11. The organic electroluminescent device according to claim 7, wherein the organic layer is a light-emitting layer.
